(19) United States
(12) Patent Application Publication
(10) Pub. No.: US 2024/0045401 A1
(43) Pub. Date: Feb. 8, 2024

(54) MANAGEMENT SYSTEM, MANAGEMENT METHOD, AND MANAGEMENT PROGRAM

(71) Applicant: Tokyo Electron Limited,, Tokyo (JP)

(72) Inventors: Tsuyoshi MORIYA, Tokyo (JP); Hironori MOKI, Miyagi (JP); Yuki KATAOKA, Hokkaido (JP); Takahito MATSUZAWA, Hokkaido (JP); Kazuya UOYAMA, Hokkaido (JP)

(21) Appl. No.: 18/258,965

(22) PCT Filed: Dec. 13, 2021
(86) PCT No.: PCT/JP2021/045779

§ 371 Date: Jun. 22, 2023

(30) Foreign Application Priority Data
Dec. 25, 2020 (JP) 2020-217779

(51) Int. Cl. G05B 19/4099

(52) U.S. Cl. CPC G05B 19/4099; G05B 2219/45031; H01L 21/67253

(57) ABSTRACT

A management system for managing a substrate manufacturing process includes agent units configured to monitor a state of a substrate processing device that performs the substrate manufacturing process and detect a predetermined event, and transmission paths configured to, when a predetermined event is detected in any one of the agent units, transmit and receive information between the agent units based on the detected event, wherein the one agent unit derives an instruction to the substrate processing device based on the information transmitted and received via the transmission paths so that an index value of the substrate manufacturing process is optimized.

### TECHNICAL FIELD

The present disclosure relates to a management system, a management method, and a management program.

### BACKGROUND ART

In recent years, in the field of substrate manufacturing processes, various efforts have been made to realize a Smart Factory. Specifically, development of digital twin Technology in which a management system collects various data (data in a physical space) measured in a substrate manufacturing process and reproduces the environment of the physical space in a cyber space has been advanced.

However, to realize a Smart Factory, it is further required to construct a mechanism for appropriately dealing with various events occurring in the physical space, and to make each substrate processing device that performs a substrate manufacturing process autonomous.

### RELATED ART DOCUMENTS

### Patent Documents

[Patent Document 1] International Publication No. 2020-050072
[Patent Document 2] Japanese Patent Application Laid-Open No. 2020-518079
[Patent Document 3] Japanese Patent Application Laid-Open No. 2018-092511

### SUMMARY OF THE INVENTION

### Problems to be Solved by the Invention

The present disclosure provides a management system, a management method, and a management program for making a substrate processing device autonomous.

### Means for Solving the Problem

According to one embodiment of the present disclosure, a management system has, for example, the following configuration. That is,
a management system for managing a substrate manufacturing process, including:
agent units configured to monitor a state of a substrate processing device that performs the substrate manufacturing process and detect a predetermined event; and
a transmission path configured to, when a predetermined event is detected in any one of the agent units, transmit and receive information between the agent units based on a detected event,
wherein the one agent unit derives an instruction to the substrate processing device based on the information transmitted and received via the transmission path so that an index value of the substrate manufacturing process is optimized.

### Effects of the Invention

According to the present disclosure, it is possible to provide a management system, a management method, and a management program for making a substrate processing device autonomous.

### BRIEF DESCRIPTION OF THE DRAWINGS

FIG. 1 is a diagram illustrating a system configuration example of a cyber-physical system including substrate processing devices that performs a substrate manufacturing process.

FIG. 2 is a diagram illustrating a hardware configuration example of a management device.

FIG. 3 is a first diagram illustrating a functional configuration example of a cyber-physical system according to a first embodiment.

FIG. 4 is a second diagram illustrating another functional configuration example of the cyber-physical system according to the first embodiment.

FIG. 5 is a third diagram illustrating another functional configuration example of the cyber-physical system according to the first embodiment.

FIG. 6 is a diagram illustrating an example of various processes performed in the cyber-physical system according to the first embodiment.

FIG. 7 is a diagram illustrating an outline of a functional configuration of a gas related digital twin.

FIG. 8 is a diagram illustrating details of the functional configuration of the gas related digital twin.

FIG. 9A is a flowchart illustrating a flow of gas flow rate control processing.

FIG. 9B is a flowchart illustrating a flow of adjustment processing.

FIG. 10 is a diagram illustrating a functional configuration example of a cyber-physical system according to a second embodiment.

FIG. 11 is a diagram illustrating an example of various processes performed in the cyber-physical system according to the second embodiment.

FIG. 12 is a diagram illustrating a functional configuration example of a cyber-physical system according to a third embodiment.

FIG. 13 is a diagram illustrating an example of various processes performed in the cyber-physical system according to the third embodiment.

FIG. 14 is a diagram illustrating a functional configuration example of a Fab layer digital twin.

FIG. 15 is a diagram illustrating details of the functional configuration of the Fab layer digital twin.

FIG. 16 is a diagram illustrating an example of conversation contents transmitted and received between levels at the time of production management processing.

FIG. 17 is a flowchart illustrating a flow of the production management processing.

### EMBODIMENTS FOR CARRYING OUT THE INVENTION

Hereinafter, embodiments will be described with reference to the accompanying drawings. In this specification and the drawings, components having substantially the same functional configuration are denoted by the same reference numerals, and redundant description thereof is omitted here.

### First Embodiment

### <System Configuration of Cyber-Physical System>

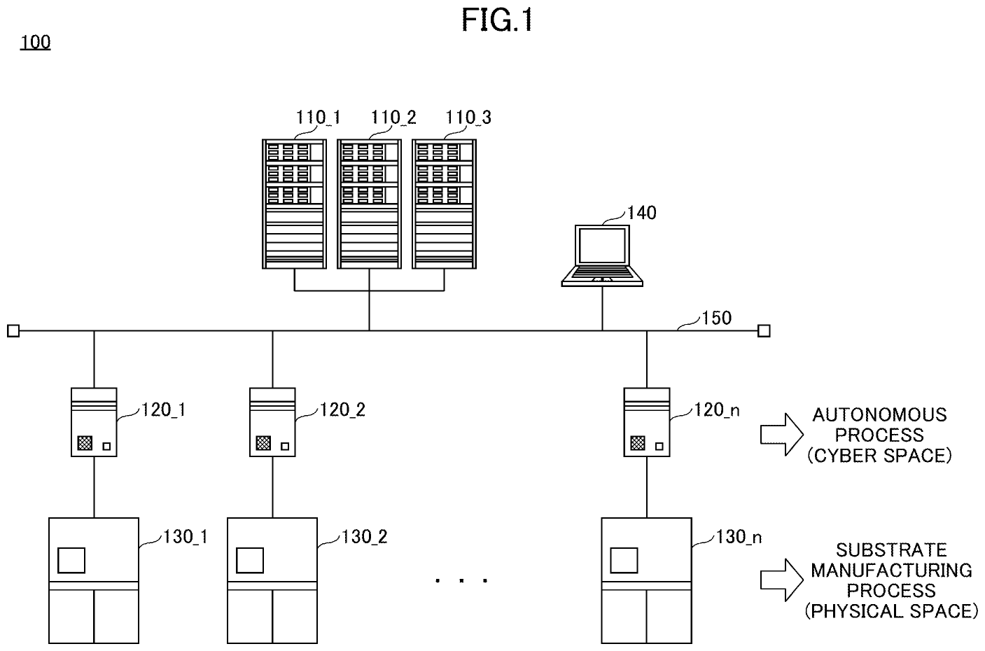

Hereinafter, a system configuration of a cyber-physical system including substrate processing devices that performs a substrate manufacturing process will be described. FIG. 1 is a diagram illustrating a system configuration example of the cyber-physical system including the processing devices that perform the substrate manufacturing process.

As illustrated in FIG. 1, a cyber-physical system 100 includes server devices 110_1 to 110_3, management devices 120_1 to 120_n, substrate processing devices 130_1 to 130_n, and an administrator terminal 140.

In the cyber-physical system 100, the server devices 110_1 to 110_3, the management devices 120_1 to 120_n, and the administrator terminal 140 are communicably connected via a network 150.

The server devices 110_1 to 110_3 are devices that control the entire cyber-physical system 100. The server devices 110_1 to 110_3 perform, for example, manufacturing management, data management, and device management of a substrate manufacturing process performed by the substrate processing devices 130_1 to 130_n, and management of models used in a cyber space by the management devices 120_1 to 120_n.

The management devices 120_1 to 120_n are connected to the substrate processing devices 130_1 to 130_n, respectively, and constitute a management system.

Further, each of the management devices 120_1 to 120_n has various kinds of models that reproduce the functionality of a corresponding substrate processing device among the substrate processing devices 130_1 to 130_n, and the management devices form the cyber space. The management devices 120_1 to 120_n collect data that are obtained by the substrate processing devices 130_1 to 130_n in a physical space to: ascertain states of the substrate processing devices 130_1 to 130_n; detect events that have occurred in the substrate processing devices 130_1 to 130_n; cooperate with each other for dealing with the detected events; instruct the substrate processing devices 130_1 to 130_n for dealing with the detected events; and the like. The management devices 120_1 to 120_n then appropriately deal with various events occurring in the physical space.

As described above, in the cyber space, the management devices 120_1 to 120_n appropriately deal with various events occurring in the substrate processing devices 130_1 to 130_n, and derive instructions to the substrate processing devices 130_1 to 130_n. Thus, the management devices 120_1 to 120_n can make the substrate processing device autonomous.

The substrate processing devices 130_1 to 130_n are devices that perform the substrate manufacturing process and form the physical space. The substrate processing devices 130_1 to 130_n include, for example, a device performing a film forming process, a device performing a lithography process, a device performing an etching process, a device performing a cleaning process, and the like. The substrate processing devices 130_1 to 130_n transmit data in the physical space obtained during the execution of the substrate manufacturing process to the management devices 120_1 to 120_n.

The administrator terminal 140 is a terminal operated by an administrator who manages the cyber-physical system 100. The administrator terminal 140 is used, for example, to form various models included in the management devices 120_1 to 120_n.

In the cyber-physical system 100 illustrated in FIG. 1, the case where the management devices 120_1 to 120_n and the substrate processing devices 130_1 to 130_n are configured as separate devices has been described. However, the management devices 120_1 to 120_n and the substrate processing devices 130_1 to 130_n may be integrally configured.

### <Hardware Configuration of Management Device>

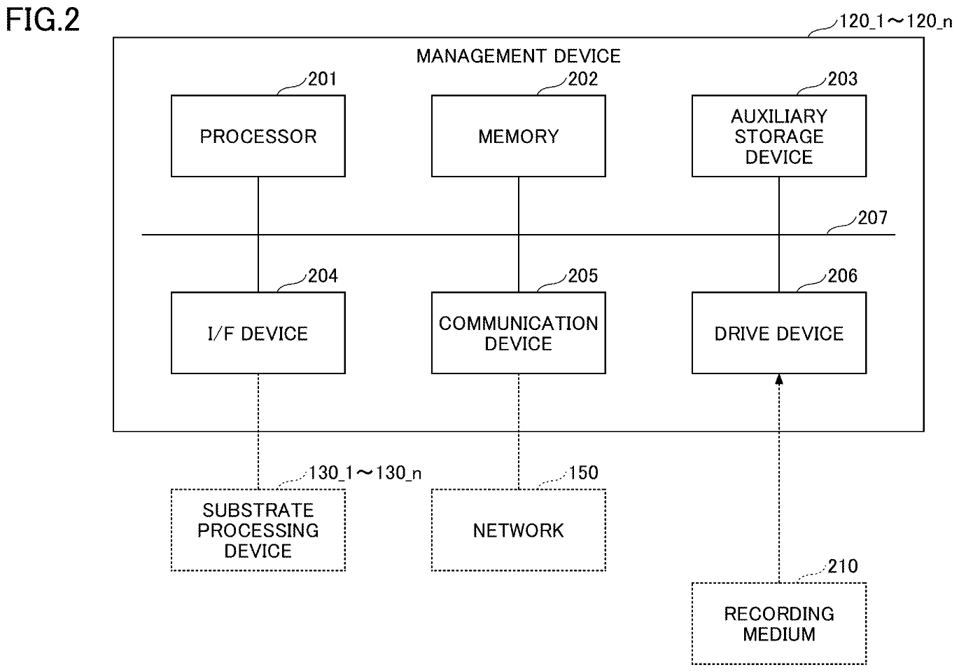

Next, hardware configurations of the management devices 120_1 to 120_n are described. Since the management devices 120_1 to 120_n have the same hardware configuration, the configuration will be collectively described with reference to FIG. 2. FIG. 2 is a diagram illustrating a hardware configuration example of the management device.

As illustrated in FIG. 2, the management devices 120_1 to 120_n include a processor 201, a memory 202, an auxiliary storage device 203, an interface (I/F) device 204, a communication device 205, and a drive device 206. The hardware components of the management devices 120_1 to 120_n are connected to each other via a bus 207.

The processor 201 includes various computing devices such as a central processing unit (CPU) and a graphics processing unit (GPU). The processor 201 reads various programs (for example, a management program which will be described later) on the memory 202 and executes the programs.

The memory 202 includes a main storage device such as a read only memory (ROM) and a random access memory (RAM). The processor 201 and the memory 202 form a so-called computer, and the computer realizes various functions by causing the processor 201 to execute various programs read out on the memory 202.

The auxiliary storage device 203 stores various programs and various types of data used when the various programs are executed by the processor 201.

The I/F device 204 is a connection device that connects the substrate processing devices 130_1 to 130_n, which are examples of external devices, and the management devices 120_1 to 120_n.

The communication device 205 is a communication device for communicating with other devices (in the present embodiment, the server devices 110_1 to 110_3, other management devices, the administrator terminal 140, and the like) via the network 150.

The drive device 206 is a device for setting a recording medium 210. The recording medium 210 may be a medium for optically, electrically, or magnetically recording information, such as a CD-ROM, a flexible disk, or a magneto-optical disk. The recording medium 210 may be a semiconductor memory or the like that electrically records information, such as a ROM or a flash memory.

The various programs installed in the auxiliary storage device 203 are installed by, for example, setting the distributed recording medium 210 in the drive device 206 and reading out the various programs recorded in the recording medium 210 by the drive device 206. Alternatively, the various programs installed in the auxiliary storage device 203 may be installed by being downloaded from a network via the communication device 205.

### <Cyber-Physical System Functional Configuration (1)>

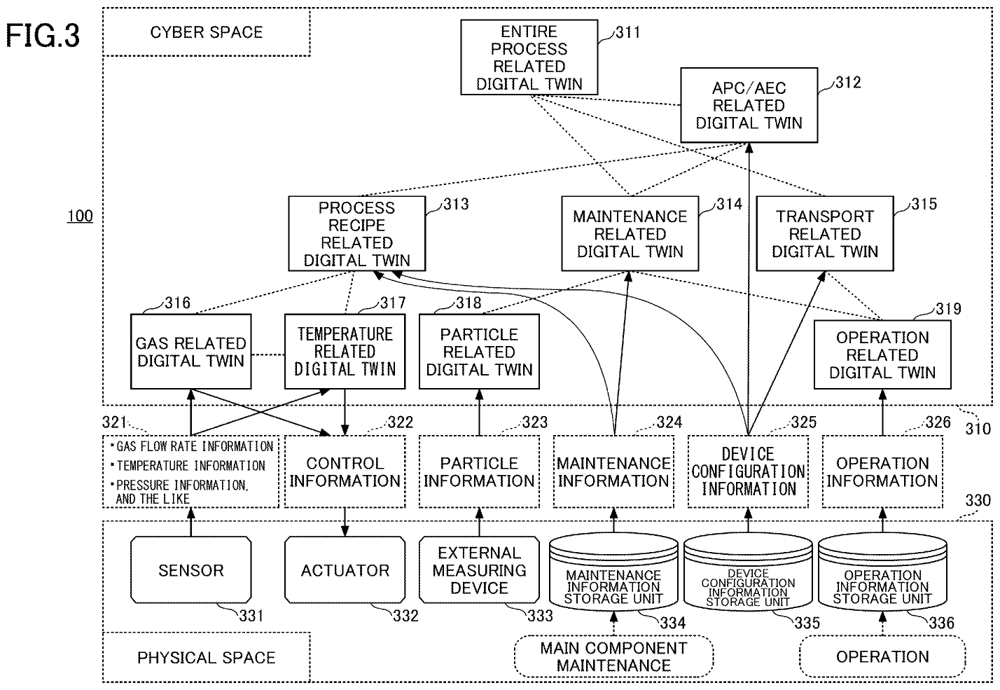

Next, a functional configuration of the cyber-physical system 100 will be described. FIG. 3 is a first diagram illustrating a functional configuration example of the cyber-physical system according to the first embodiment.

As illustrated in FIG. 3, a cyber space 310 formed by each of the management devices 120_1 to 120_n includes digital twins including various models that reproduce the functionality of a corresponding substrate processing device among the substrate processing devices 130_1 to 130_n.

The example in FIG. 3 illustrates that the digital twins include an entire process related digital twin 311, an APC/AEC related digital twin 312, a process recipe related digital twin 313, and a maintenance related digital twin 314. Further, the example in FIG. 3 illustrates that the digital twins include a transport related digital twin 315, a gas related digital twin 316, a temperature related digital twin 317, a particle related digital twin 318, and an operation related digital twin 319.

As illustrated in FIG. 3, each digital twin included in the cyber space 310 is connected to some of the other digital twins via transmission paths (see the dotted lines in the cyber space 310) and transmits and receives information to and from the connected digital twin(s). For example, the entire process related digital twin 311 is connected to the APC/AEC related digital twin 312, the maintenance related digital twin 314, and the transport related digital twin 315 via the transmission paths, and transmits and receives information thereto and therefrom.

It is assumed that the direction of transmitting and receiving information between the source digital twin and the destination digital twin connected via the transmission path is defined in advance.

Further, as illustrated in FIG. 3, data in a physical space 330 is input into specific digital twins included in the cyber space 310. Accordingly, the specific digital twins included in the cyber space 310 can ascertain states, detect events, cooperate with the other digital twins, instruct the substrate processing devices, and the like (hereinafter, these are referred to as “digital twin processing”).

The example in FIG. 3 illustrates that the gas related digital twin 316 performs the digital twin processing when the gas related digital twin 316 receives information 321 including gas flow rate information, temperature information, pressure information, and the like as the data in the physical space. Note that, in the example in FIG. 3, the gas related digital twin 316 transmits and receives information to and from the process recipe related digital twin 313 and the temperature related digital twin 317 when cooperating with the other digital twins.

The example in FIG. 3 illustrates that the temperature related digital twin 317 performs the digital twin processing when the temperature related digital twin 317 receives the information 321 including the gas flow rate information, the temperature information, the pressure information, and the like as the data in the physical space. Note that, in the example in FIG. 3, the temperature related digital twin 317 transmits and receives information to and from the process recipe related digital twin 313 and the gas related digital twin 316 when cooperating with the other digital twins.

The example in FIG. 3 illustrates that the particle related digital twin 318 performs the digital twin processing when the particle related digital twin 318 receives particle information 323 as the data in the physical space. Note that, in the example in FIG. 3, the particle related digital twin 318 transmits and receives information to and from the maintenance related digital twin 314 when cooperating with the other digital twin.

The example in FIG. 3 illustrates that the process recipe related digital twin 313 performs the digital twin processing when the process recipe related digital twin 313 receives maintenance information 324 and device configuration information 325 as the data in the physical space. Note that, in the example in FIG. 3, the process recipe related digital twin 313 transmits and receives information to and from the gas related digital twin 316, the temperature related digital twin 317, and the APC/AEC related digital twin 312 when cooperating with the other digital twins.

The example in FIG. 3 illustrates that the maintenance related digital twin 314 performs the digital twin processing when the maintenance related digital twin 314 receives the maintenance information 324 as the data in the physical space. Note that, in the example in FIG. 3, the maintenance related digital twin 314 transmits and receives information to and from the particle related digital twin 318 and the operation related digital twin 319 when cooperating with the other digital twins. Further, the maintenance related digital twin 314 transmits and receives information to and from the APC/AEC related digital twin 312 and the entire process related digital twin 311 when cooperating with the other digital twins.

The example in FIG. 3 illustrates that the operation related digital twin 319 performs the digital twin processing when the operation related digital twin 319 receives operation information as the data in the physical space. Note that, in the example in FIG. 3, the operation related digital twin 319 transmits and receives information to and from the maintenance related digital twin 314 and the transportation related digital twin 315 when cooperating with the other digital twins.

The example in FIG. 3 illustrates that the transport related digital twin 315 performs the digital twin processing when the transport related digital twin 315 receives the device configuration information 325 as the data in physical space. Note that, in the example in FIG. 3, the transport related digital twin 315 transmits and receives information to and from the entire process related digital twin 311 and the operation related digital twin 319 when cooperating with the other digital twins.

The example in FIG. 3 illustrates that the APC/AEC related digital twin 312 performs the digital twin processing when the APC/AEC related digital twin 312 receives the device configuration information 325 as the data in the physical space. Note that, in the example in FIG. 3, the APC/AEC related digital twin 312 transmits and receives information to and from the entire process related digital twin 311, the process recipe related digital twin 313, and the maintenance related digital twin 314 when cooperating with the other digital twins.

With respect to the above, the physical space 330 formed by the substrate processing devices 130_1 to 130_n includes elements for providing data input into the cyber space 310 or elements to which instructions from the cyber space 310 are transmitted.

The example in FIG. 3 illustrates that, a sensor 331, an external measuring device 333, a maintenance information storage unit 334, a device configuration information storage unit 335, and an operation information storage unit 336 are included as the elements for providing the data input into the cyber space 310. The example in FIG. 3 also illustrates that an actuator 332 is included as the element to which the instructions from the cyber space 310 are transmitted.

The sensor 331 measures the information 321 including the gas flow rate information, the temperature information, the pressure information, and the like. The information 321 including the gas flow rate information, the temperature information, the pressure information, and the like measured by the sensor 331 is input into the cyber space 310 as the data in the physical space.

The external measuring device 333 measures the particle information 323. The particle information 323 measured by the external measuring device 333 is input into the cyber space 310 as the data in the physical space. The device for measuring the particle information 323 is not limited to the external measuring device, and may be an internal measuring device installed in the substrate processing devices 130_1 to 130_n. For example, the device for measuring the particle information 323 may be a device that measures internal states of the substrate processing devices 130_1 to 130_n through windows provided in walls of the substrate processing devices 130_1 to 130_n. The device for measuring the particle information 323 may be a device that observes the state on a substrate to be processed or a device that acquires the state of a processing space in which the substrate to be processed is processed.

The maintenance information storage unit 334 stores the maintenance information 324 related to maintenance (repair, replacement) of main components of the substrate processing device performed in the physical space 330. The maintenance information 324 stored in the maintenance information storage unit 334 is input into the cyber space 310 as the data in the physical space.

The device configuration information storage unit 335 stores the device configuration information 325 indicating a device configuration of each of the substrate processing devices 130_1 to 130_n in the physical space 330. The device configuration information 325 stored in the device configuration information storage unit 335 is input into the cyber space 310 as the data in the physical space.

The operation information storage unit 336 stores the operation information 326 indicating various operations performed on the substrate processing devices in the physical space 330. The operation information 326 stored in the operation information storage unit 336 is input into the cyber space 310 as the data in the physical space.

The actuator 332 operates based on an instruction from the cyber space 310. The example in FIG. 3 illustrates that the actuator 332 operates based on control information 322 (an example of a control value) calculated by the gas related digital twin 316 and the temperature related digital twin 317.

### <Cyber-Physical System Functional Configuration (2)>

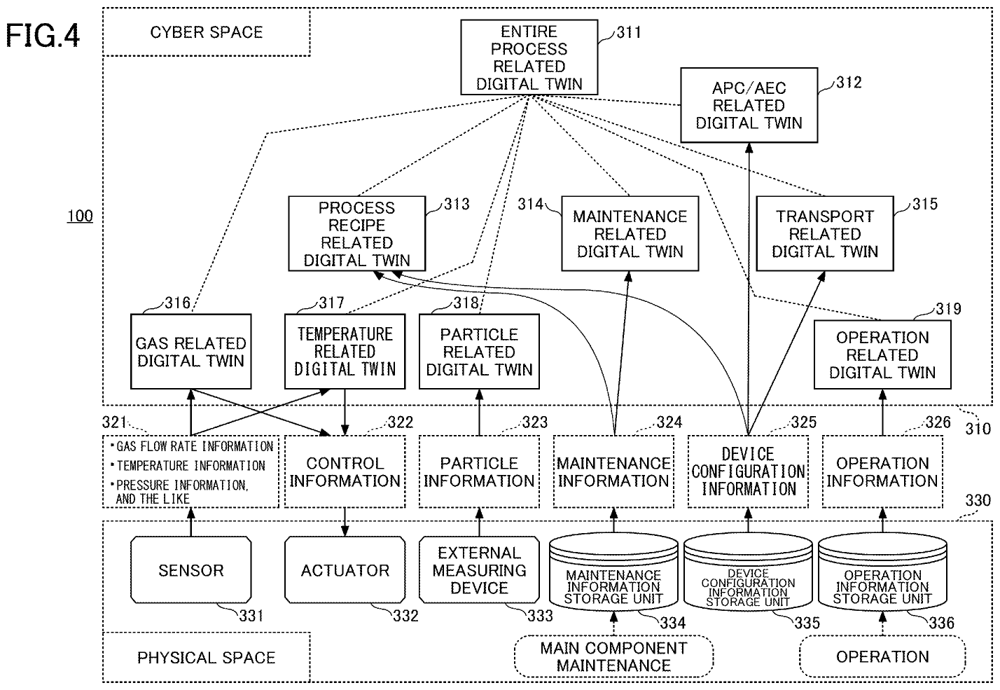

As another functional configuration of the cyber-physical system 100, a functional configuration in which the transmission path connection mode is different from that in FIG. 3 will be described. FIG. 4 is a second diagram illustrating a functional configuration example of the cyber-physical system according to the first embodiment.

The difference from FIG. 3 is that, in the case of FIG. 4, each of the digital twins other than the entire process related digital twin 311 is connected to the entire process related digital twin 311 via the transmission path.

For example, the APC/AEC related digital twin 312 is connected to the entire process related digital twin 311 via the transmission path, and transmits and receives information to and from the entire process related digital twin 311. The process recipe related digital twin 313 is also connected to the entire process related digital twin 311 via the transmission path, and transmits and receives information to and from the entire process related digital twin 311. The same applies to the maintenance related digital twin 314 to the operation related digital twin 319.

### <Cyber-Physical System Functional Configuration (3)>

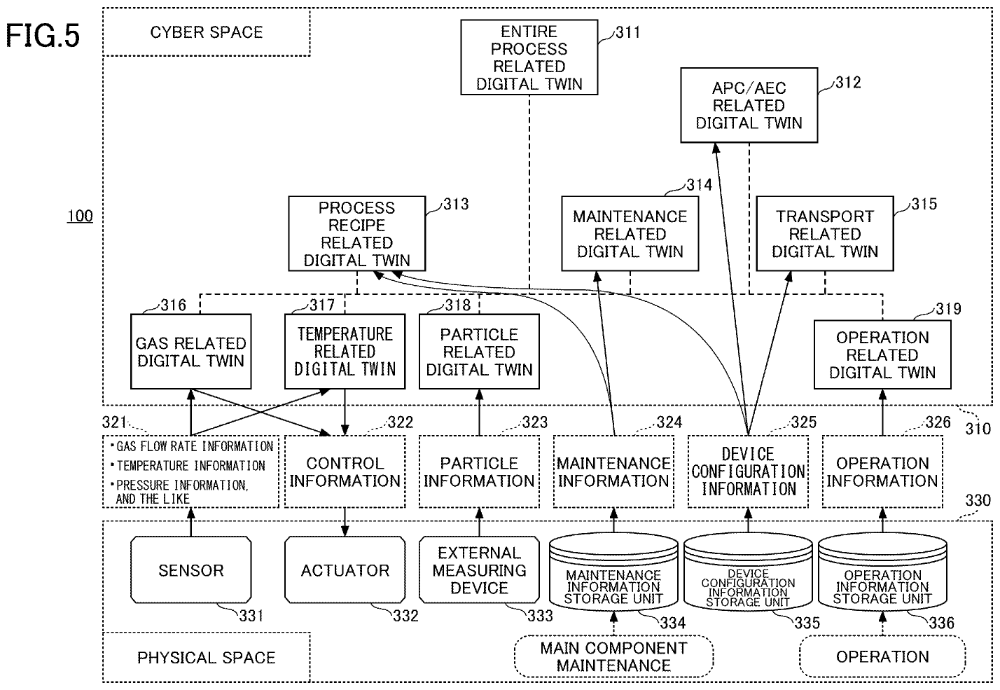

Next, as another functional configuration of the cyber-physical system 100, a functional configuration in which the transmission path connection mode is different from that in FIG. 3 and FIG. 4 will be described. FIG. 5 is a third diagram illustrating a functional configuration example of the cyber-physical system according to the first embodiment.

The difference from FIG. 3 and FIG. 4 is that, in the case of FIG. 5, all the digital twins are connected to one another via the transmission paths.

For example, the entire process related digital twin 311 to the transportation related digital twin 315 and the temperature related digital twin 317 to the operation related digital twin 319 are connected to the gas related digital twin 316 via the transmission paths. That is, the gas related digital twin 316 transmits and receives information to and from the digital twins other than the gas related digital twin 316.

Similarly, the entire process related digital twin 311, the APC/AEC related digital twin 312, and the maintenance related digital twin 314 to the operation related digital twin 319 are connected to the process recipe related digital twin 313 via the transmission paths. That is, the process recipe related digital twin 313 transmits and receives information to and from the digital twins other than the process recipe related digital twin 313. The same applies to the other digital twins.

### <Various Processes Performed in Cyber-Physical System>

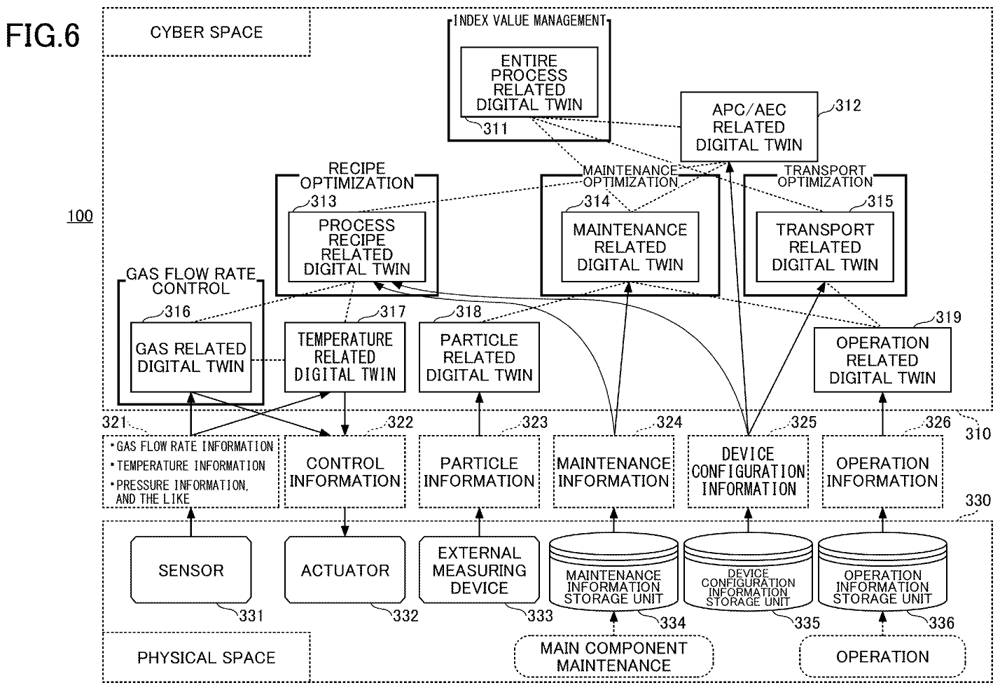

Next, various processes performed in the cyber-physical system 100 will be described. FIG. 6 is a diagram illustrating an example of various processes performed in the cyber-physical system according to the first embodiment. Note that FIG. 6 illustrates an example of various processes performed when the transmission path connection mode is the connection mode illustrated in FIG. 3.

In FIG. 6, a process indicated by a thick black frame represents an example of a process performed mainly by a corresponding digital twin. As illustrated in FIG. 6, for example, the entire process related digital twin 311 performs index value management processing.

The index value management processing is processing for managing an index value for the entire substrate manufacturing process. The index value includes sub-index values such as a yield of the entire substrate manufacturing process, a processing amount per unit time of the entire substrate manufacturing process, and energy consumption of the entire substrate manufacturing process.

The entire process related digital twin 311 obtains sub-index values by transmitting and receiving information to and from other digital twins via the transmission paths, for example, and calculates the index value of the entire substrate manufacturing process based on the obtained sub-index values. Further, the entire process related digital twin 311 transmits various instructions to other digital twins to optimize the calculated index value.

The index value management value management processing performed by the entire process related digital twin 311 is related to various types of processing performed mainly by the other digital twins. That is, the various types of processing performed mainly by the other digital twins are performed to optimize the index value of the entire substrate manufacturing process.

Recipe optimization processing is processing for optimizing a process recipe. The recipe optimization processing includes optimization of a substrate processing time or a substrate processing amount in addition to optimization of substrate processing quality in a predetermined device state (a component consumption state, a deposition state on a chamber inner wall, or the like).

The process recipe related digital twin 313 ascertains current device states by transmitting and receiving information to and from other digital twins via the transmission paths, and derives an optimum process recipe for the ascertained device states from a learning result based on the past data.

Maintenance optimization processing is processing for optimizing a target component to be replaced or repaired among the main components constituting the substrate processing device and a timing at which the target component is replaced or repaired.

The maintenance related digital twin 314, for example, by transmitting and receiving information to and from other digital twins via the transmission paths, ascertains the consumption state of each main component, and predicts the lifetime of each main component based on the operation state of the device in the future. The maintenance related digital twin 314 then derives an optimum timing at which each main component is required to be replaced or repaired based on the corresponding predicted lifetime.

Transport optimization processing is processing for optimizing the transport of the substrate. The transport optimization processing includes maximization of a processing amount per unit time by the substrate processing device and the like.

The transport related digital twin 315, for example, by transmitting and receiving information to and from other digital twins via the transmission paths, ascertains a processing amount to be processed by the substrate processing device, and derives an optimum transport method for processing the ascertained processing amount from a learning result based on the past data.

Gas flow rate control processing is processing for deriving control information by which a flow rate of a gas used for processing a substrate becomes a predetermined target value.

For example, when a certain event occurs in the substrate processing device, the gas related digital twin 316 calculates a target value that can be achieved by the substrate processing device, by transmitting and receiving information to and from other digital twins via the transmission paths, and derives control information for achieving the calculated target value.

The various processes illustrated in FIG. 6 are examples of processes performed in the cyber-physical system 100, and each digital twin described above may perform a process other than the above-described processes. Further, the digital twin to mainly perform each process is not limited to the digital twin illustrated in FIG. 6. Any digital twin whose processing is not illustrated in FIG. 6 may mainly perform any processing.

Hereinafter, among the various processes illustrated in FIG. 6, the gas flow rate control processing performed by the gas related digital twin 316 will be described in detail.

### <Outline of Gas Related Digital Twin Functional Configuration>

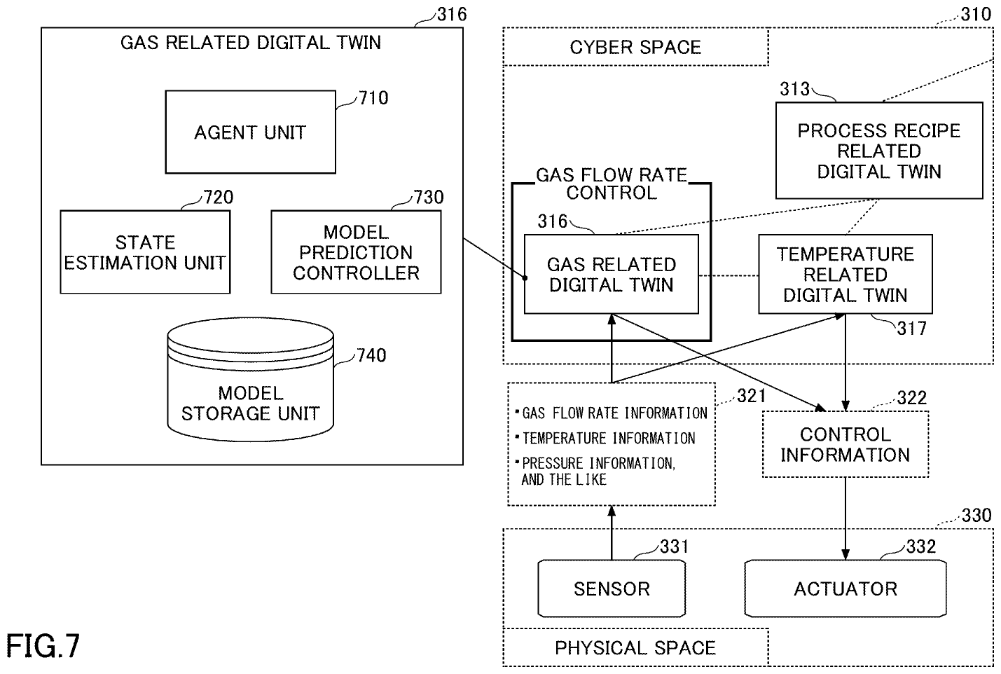

First, an outline of a functional configuration of the gas related digital twin that performs the gas flow rate control processing will be described. FIG. 7 is a diagram illustrating an outline of a gas related digital twin functional configuration. In FIG. 7, the cyber space 310 and the physical space 330 indicate the elements and the digital twins related to the gas related digital twin 316 extracted of the cyber space 310 and the physical space 330 illustrated in FIG. 3. In FIG. 7, among the data input into the cyber space 310 and the instructions to the substrate processing device in the physical space 330, the data and the instructions related to the gas related digital twin 316 are illustrated.

The gas related digital twin 316 includes an agent unit 710, a state estimation unit 720, and a model prediction controller 730 as functional blocks for performing the gas flow rate control processing. A model of each unit is stored in a model storage unit 740, and is read from the model storage unit 740 when the gas flow rate control processing is performed.

The agent unit 710 manages the state estimation unit 720 and the model prediction controller 730. Specifically, the agent unit 710 ascertains the state of the substrate processing device, estimated by the state estimation unit 720, in real time, and monitors whether an event requiring a change in the target value in the gas flow rate control processing occurs.

When it is determined that an event requiring a change in the target value in the gas flow rate control processing occurs, the agent unit 710 changes the target value. At this time, the agent unit 710 determines whether it is necessary to transmit and receive information to and from the agent unit of another digital twin (that is, between the agent units), and when it is determined that it is necessary, the target value is changed after transmitting and receiving information to and from the other digital twin. The agent unit 710 also notifies the model prediction controller 730 of the changed target value.

The state estimation unit 720 obtains the information 321 including the gas flow rate information, the temperature information, the pressure information, and the like measured by the sensor 331, and estimates the state of a gas flow rate control system, which is a control target of the gas flow rate control processing of the substrate processing device. The state estimation unit 720 also notifies the agent unit 710 of the estimated state of the gas flow rate control system.

The model prediction controller 730 is an example of a controller, and derives the control information 322 for achieving the changed target value notified by the agent unit 710. The model prediction controller 730 transmits the derived control information 322 as an instruction to the substrate processing device (specifically, the actuator 332 in the physical space 330).

### <Details of Gas Related Digital Twin Functional Configuration>

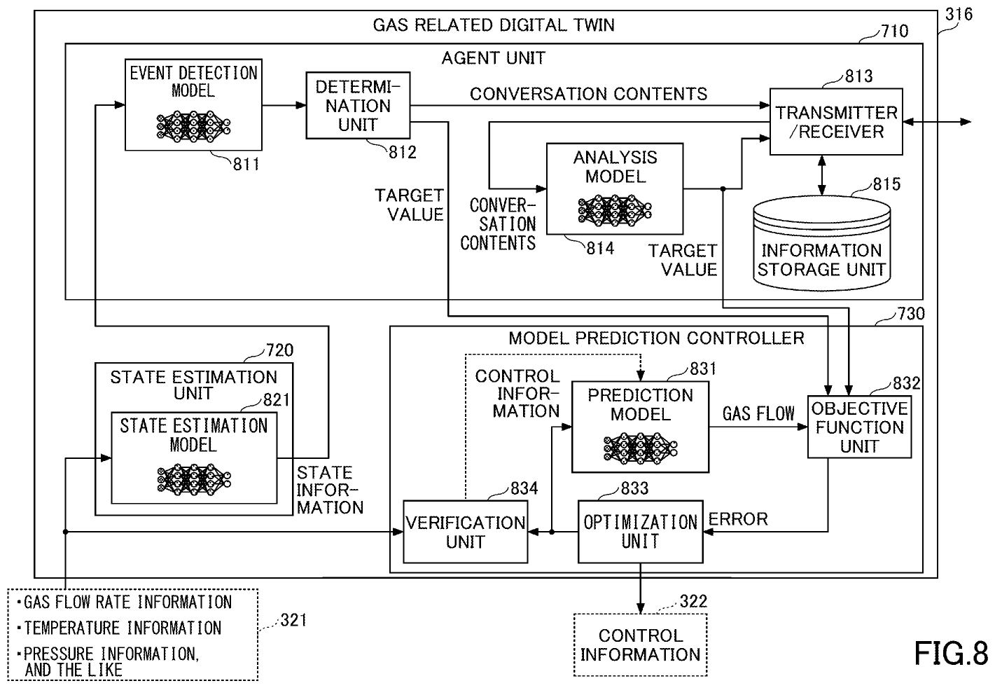

Next, a functional configuration of the gas related digital twin 316 that performs the gas flow rate control processing will be described in detail. FIG. 8 is a diagram illustrating details of a gas related digital twin functional configuration.

As illustrated in FIG. 8, the state estimation unit 720 is an example of an acquisition unit and includes a state estimation model 821. The state estimation model 821 estimates, for example, state information indicating a state of the gas flow rate control system of the substrate processing device 130_1, using the information 321 including the gas flow rate information, the temperature information, the pressure information, and the like as input.

The agent unit 710 includes an event detection model 811, a determination unit 812, a transmitter/receiver 813, and an analysis model 814.

The event detection model 811 is an example of a detector, and estimates whether an event requiring a change in the target value in the gas flow rate control processing occurs and the type of the event, using the state information estimated by the state estimation model 821 as input.

When the event detection model 811 estimates that the event requiring a change in the target value has occurred, the determination unit 812 obtains the type of the event from the event detection model 811. The determination unit 812 also calculates a target value according to the obtained event type, notifies the model prediction controller 730 of the target value, determines control availability, and then determines whether it is necessary to transmit and receive information to and from another digital twin.

When it is determined that control is available, the determination unit 812 determines that transmission and reception of information to and from another digital twin are unnecessary. When it is determined that control is not available, the determination unit 812 determines that transmission and reception of information to and from another digital twin are necessary.

When it is determined that transmission and reception of information to and from another digital twin are necessary, the determination unit 812 notifies the transmitter/receiver 813 of conversation contents including the target value calculated according to the type of the event.

The transmitter/receiver 813 transmits and receives the conversation contents between the gas related digital twin 316 and another digital twin (in the case of FIG. 7, the process recipe related digital twin 313 and the temperature related digital twin 317).

For example, the transmitter/receiver 813 transmits the conversation contents notified from the determination unit 812 to another digital twin. The transmitter/receiver 813 also receives the conversation contents (response) transmitted from another digital twin and inputs the conversation contents into the analysis model 814. Further, the transmitter/receiver 813 retransmits the conversation contents output from the analysis model 814 to another digital twin. The conversation contents transmitted to and received from another digital twin by the transmitter/receiver 813 are stored in an information storage unit 815.

The analysis model 814 outputs conversation contents to be transmitted to another digital twin, using the conversation contents (response) notified from the transmitter/receiver 813 as input. In the case of the gas flow rate control processing, an allowable target value, a constraint condition, or the like is transmitted from another digital twin, with respect to the target value transmitted to another digital twin. The analysis model 814 then calculates a new target value using the allowable target value, the constraint condition, or the like, transmitted from another digital twin as input.

The analysis model 814 calculates an appropriate target value by repeating the transmission and reception of the conversation contents with another digital twin, and notifies the model prediction controller 730 of the target value.

It is assumed that various instructions transmitted from the entire process related digital twin 311 for optimizing the index value of the entire substrate manufacturing process are reflected in the conversation contents (response) transmitted from another digital twin to the transmitter/receiver 813. That is, the analysis model 814 calculates the target value to optimize the index value of the entire substrate manufacturing process.

The model prediction controller 730 includes a prediction model 831, an objective function unit 832, an optimization unit 833, and a verification unit 834.

The prediction model 831 is obtained by modeling behavior of the gas flow rate control system (behavior of the sensor 331, the actuator 332, and a controller (not illustrated)) in the physical space 330, and predicts a gas flow rate, using the control information as input.

The objective function unit 832 calculates an error between the gas flow rate predicted by the prediction model 831 and the target value, and notifies the optimization unit 833 of the error.

The optimization unit 833 searches for the control information that reduces the error notified from the objective function unit 832. The optimization unit 833 also sends the searched control information to the prediction model 831, and obtains the error between the gas flow rate predicted by the prediction model 831 and the target value again. The optimization unit 833 minimizes the error by repeating the above-described processes, and derives the optimum control information 322.

The optimization unit 833 also transmits the optimum control information 322 as an instruction to the substrate processing device (specifically, the actuator 332 of the physical space 330).

The verification unit 834 obtains the optimum control information 322 from the optimization unit 833. The verification unit 834 also obtains the gas flow rate information provided from the physical space 330 in accordance with the optimum control information 322 being transmitted as an instruction to the substrate processing device (specifically, the actuator 332 in the physical space 330).

Further, the verification unit 834 determines whether the control information 322 is appropriate based on the optimum control information 322 and the obtained gas flow rate information, verifies the prediction accuracy of the prediction model 831, and adjusts the model parameters of the prediction model 831 as necessary. The verification unit 834 then can match the prediction model 831 with the behavior of the gas flow rate control system in the physical space 330.

### <Gas Flow Rate Control Processing Flow>

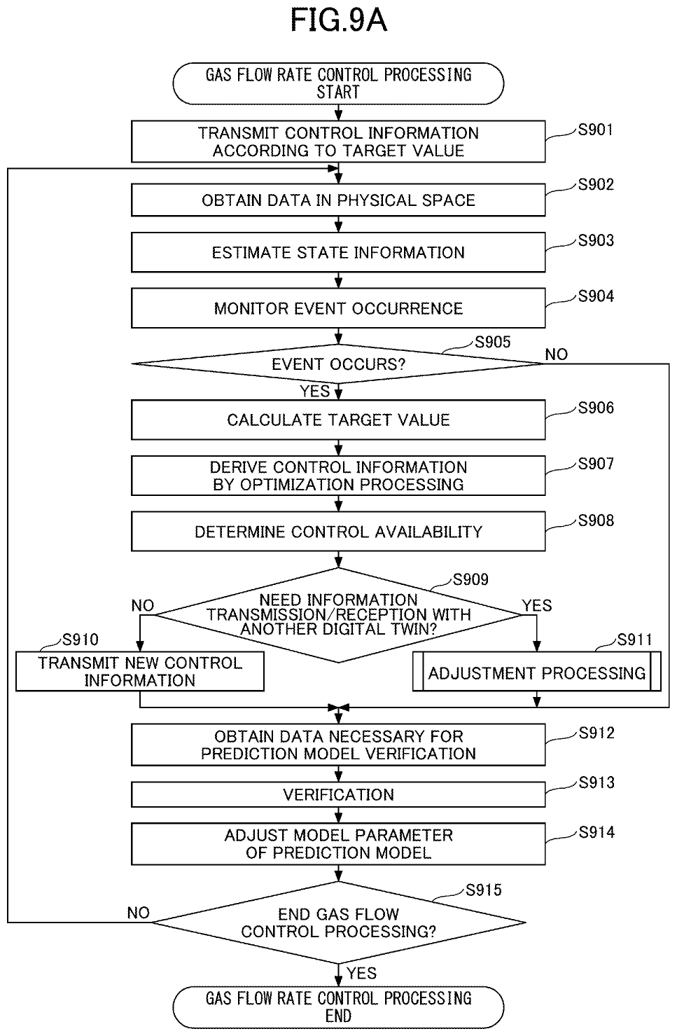

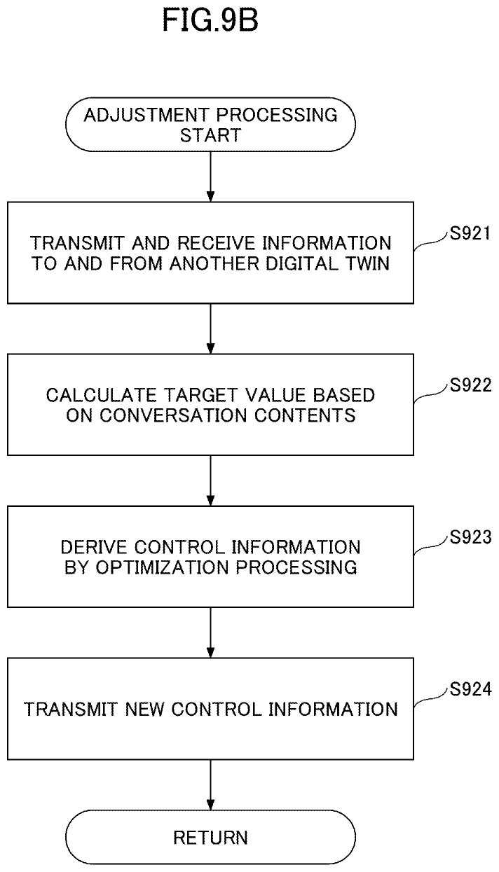

Next, a flow of the gas flow rate control processing by the gas related digital twin 316 will be described. FIG. 9A is a flowchart illustrating a flow of the gas flow rate control processing.

In step S901, the model prediction controller 730 obtains a target value, and derives control information in accordance with the obtained target value. The model prediction controller 730 also transmits the derived control information as an instruction to the substrate processing device in the physical space 330.

In step S902, the state estimation unit 720 obtains the information 321 including the gas flow-rate information, the temperature-information, the pressure information, and the like, from the physical space 330.

In step S903, the state estimation unit 720 estimates the state information indicating the state of the gas flow rate control system of the substrate processing device based on the obtained data in the physical space.

In step S904, based on the state information estimated by the state estimation unit 720, the agent unit 710 monitors whether an event requiring a change in the target value occurs.

In step S905, the agent unit 710 determines whether the event requiring a change in the target value in the gas flow rate control processing has occurred, and determines the type of the event. When it is determined in step S905 that no event has occurred (NO in step S905), the process proceeds to step S912.

When it is determined in step S905 that the event has occurred (YES in step S905), the process proceeds to step S906.

In step S906, the agent unit 710 calculates a target value according to the type of the event that has occurred.

In step S907, the model prediction controller 730 performs the optimization processing to derive control information that minimizes the error from the calculated target value.

In step S908, the agent unit 710 determines control availability based on the error from the target value after the optimization processing is performed by the model prediction controller 730 in step S907.

To be more specific, if the error between the output value of the prediction model 831 used when the control information has been derived in step S907 and the target value is equal to or larger than a threshold value and control information that minimizes the error is not derived, the agent unit 710 determines that the control is not available. That is, when the output value cannot be approached to the target value even if the optimization processing is performed, the agent unit 710 determines that the control is not available. When the error between the output value of the prediction model 831 used when the control information has been derived in step S907 and the target value is less than the threshold value and control information that minimizes the error is derived, the agent unit 710 determines that the control is available. That is, when the output value is approached to the target value by performing the optimization processing, the agent unit 710 determines that the control is available.

In step S909, the agent unit 710 determines whether transmission/reception of information to/from another digital twin is necessary based on the determination result of the control availability.

To be more specific, when it is determined in step S908 that control is available, the agent unit 710 determines that the output value can be approached to the target value, independently. Therefore, in step S909, the agent unit 710 determines that transmission/reception of information to/from another digital twin is not necessary (determines NO in step S909), and proceeds to step S910.

In step S910, the model prediction controller 730 transmits the derived new control information as an instruction to the substrate processing device in the physical space 330.

When it is determined in step S908 that the control is not available, the agent unit 710 determines that the output value cannot be approached to the target value, independently. Therefore, in step S909, the agent unit 710 determines that transmission/reception of information to/from another digital twin is necessary (determines YES in step S909), and proceeds to step S911.

In step S911, the agent unit 710 performs adjustment processing, transmits and receives information to and from another digital twin, and derives new control information. Details of the adjustment processing are as illustrated in FIG. 9B. FIG. 9B is a flowchart illustrating an adjustment processing flow.

In step S921, the agent unit 710 transmits the conversation contents including the target value calculated in step S906 in FIG. 9A to another digital twin, and receives the conversation contents (response) transmitted from another digital twin.

In step S922, the agent unit 710 calculates a new target value in the gas flow rate control processing by transmitting and receiving the conversation contents to and from another digital twin.

In step S923, the model prediction controller 730 performs the optimization processing to derive control information that minimizes the error from the calculated new target value.

In step S924, the model prediction controller 730 transmits the derived new control information as an instruction to the substrate processing device in the physical space 330. The process then returns to step S912 in FIG. 9A.

In step S912, the model prediction controller 730 obtains the data in the physical space 330 necessary for verification of the prediction model from the physical space 330.

In step S913, the model prediction controller 730 verifies the prediction accuracy of the prediction model 831 based on the control information transmitted to the physical space 330 and the data obtained from the physical space 330.

In step S914, the model prediction controller 730 adjusts the model parameters of the prediction model 831 based on the verified prediction accuracy of the prediction model 831.

In step S915, the agent unit 710 determines whether to end the gas flow rate control processing, and when it is determined to continue the gas flow rate control processing (NO in step S915), the process returns to step S902.

When it is determined in step S915 that the gas flow rate control processing is to be ended (YES in step S918), the gas flow rate control processing is ended.

### SUMMARY

As is clear from the above description, in the cyber-physical system 100, the management system that forms the cyber space and manages the substrate manufacturing process in the physical space includes:
digital twins respectively including agent units that monitor a state of a corresponding substrate processing device and detect that a predetermined event has occurred; and
a transmission path, connecting the digital twins, through which, when the predetermined event is detected in an agent unit of any one of the digital twins, information is transmitted to and received from an agent unit in another digital twin, based on the detected event;
wherein the agent unit in which the predetermined event is detected derives an instruction to the substrate processing device based on the information transmitted and received via the transmission path so that an index value of the substrate manufacturing process is optimized.

As described above, in the management system according to the first embodiment, the agent units and the transmission path are arranged in the cyber space, and the digital twins are cooperated with each other, thereby appropriately dealing with events occurring in the physical space and deriving instructions to the substrate processing device. Thus, according to the management system of the first embodiment, each substrate processing device can be made autonomous.

That is, according to the first embodiment, it is possible to provide a management system that makes a substrate processing device autonomous.

### Second Embodiment

In the first embodiment, the case in which one cyber space 310 is formed in the cyber-physical system is described. However, the number of cyber spaces formed in the cyber-physical system is not limited to one, and multiple cyber spaces may be formed. In addition, digital twins (specifically, the agent units) respectively included in the formed cyber spaces may be connected to each other via the transmission path to transmit and receive information between the digital twins included in different cyber spaces. The second embodiment will be described below focusing on differences from the first embodiment.

### <Functional Configuration of Cyber-Physical System>

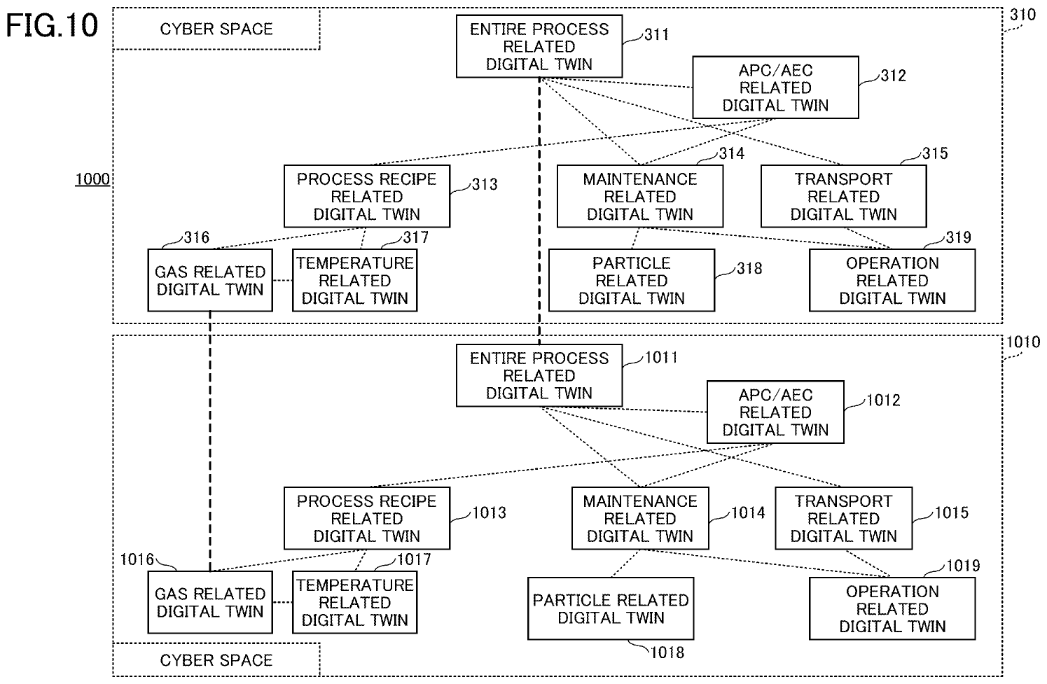

First, a functional configuration of a cyber-physical system according to the second embodiment will be described. FIG. 10 is a diagram illustrating a functional configuration example of the cyber-physical system according to the second embodiment.

As illustrated in FIG. 10, a cyber-physical system 1000 includes cyber spaces (the cyber space 310 and a cyber space 1010). In FIG. 10, physical spaces corresponding to cyber spaces are omitted for convenience of paper space, but for example, it is assumed that the cyber space 310 is a cyber space corresponding to the physical space 330 in FIG. 3. Further, the cyber space 1010 is assumed to be a cyber space corresponding to a physical space having the same configuration as that of the physical space 330 in FIG. 3 in a factory (Fab: Fabrication) different from the physical space 330 in FIG. 3.

The cyber space 1010 illustrated in FIG. 10 includes digital twins substantially the same as those of the cyber space 310 (see an entire process related digital twin 1011 to an operation related digital twin 1019).

Furthermore, it is assumed that the transmission paths connecting respective digital twins included in the cyber space 1010 illustrated in FIG. 10 have the same connection mode as the transmission paths connecting respective digital twins included in the cyber space 310.

However, in the case of FIG. 10, the entire process related digital twin 311 in the cyber space 310 and the entire process related digital twin 1011 in the cyber space 1010 are connected via a transmission path (see the thick dotted line). Similarly, in the case of FIG. 10, the gas related digital twin 316 in the cyber space 310 and a gas related digital twin 1016 in the cyber space 1010 are connected via a transmission path (see the thick dotted line).

As described above, it is possible to optimize across the physical spaces by connecting the digital twins included in the different cyber spaces via the transmission path and transmitting and receiving information between the digital twins included in the different cyber spaces.

### <Various Processes Performed in Cyber-Physical System>

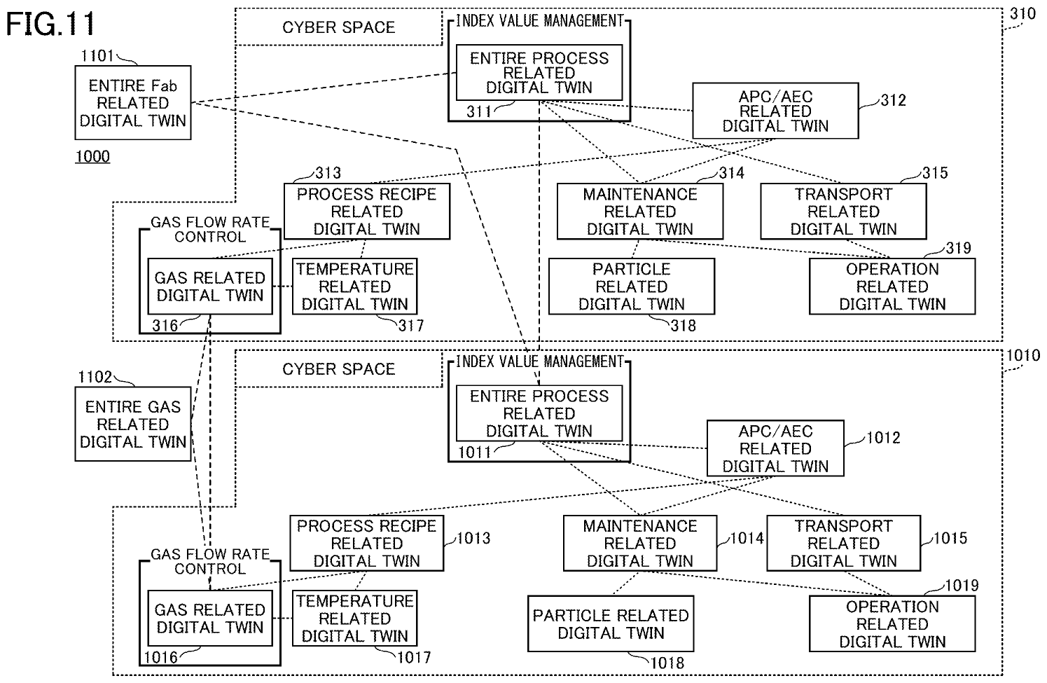

Next, various processes performed in the cyber-physical system 1000 according to the second embodiment will be described. FIG. 11 is a diagram illustrating an example of various processes performed in the cyber-physical system according to the second embodiment. In the example in FIG. 11, only the processing performed by the digital twins (the entire process related digital twin and the gas related digital twin) connected via the transmission paths in the different cyber spaces is illustrated.

As illustrated in FIG. 11, in the cyber space 310, the entire process related digital twin 311 performs the index value management processing. Similarly, in the cyber space 1010, the entire process related digital twin 1011 performs the index value management processing.

Since the index value management processing performed in each of the entire process relevant digital twins 311 and 1011 has already been described in the first embodiment, the description thereof is omitted here.

However, the entire process related digital twin 311 transmits various instructions to other digital twins included in the cyber space 310 to optimize the index value of the entire substrate manufacturing process while transmitting and receiving information to and from the entire process related digital twin 1011.

Similarly, the entire process related digital twin 1011 transmits various instructions to other digital twins included in the cyber space 1010 to optimize the index value of the entire substrate manufacturing process while transmitting and receiving information to and from the entire process related digital twin 311.

As illustrated in FIG. 11, the entire process related digital twin 311 and the entire process related digital twin 1011 may be connected via the transmission paths to an entire Fab related digital twin 1101 that controls them.

The Fab entire related digital twin 1101 controls the process entire related digital twin included in each of the cyber spaces. To be more specific, the entire Fab related digital twin 1101 transmits and receives information to and from the entire process related digital twins 311 and 1011, and transmits various instructions to each digital twin to optimize the index value of the entire Fab (that is, the entire physical space).

Note that the entire Fab related digital twin 1101 may be in one of the cyber spaces 310 and 1010, or may be in a cyber space formed by other devices (for example, the server devices 110_1 to 110_3).

As illustrated in FIG. 11, the gas related digital twin 316 performs the gas flow rate control processing in the cyber space 310. Similarly, in the cyber space 1010, the gas related digital twin 1016 performs the gas flow rate control processing.

Since the gas flow rate control processing performed in each of the gas related digital twins 316 and 1016 has already been described in the first embodiment, the description thereof is omitted here.

However, the gas related digital twin 316 calculates a target value that can be achieved by the substrate processing device, while transmitting and receiving information to and from the gas related digital twin 1016 as well as the process recipe related digital twin 313 and the temperature related digital twin 317.

Similarly, the gas related digital twin 1016 calculates a target value that can be achieved by the substrate processing device, while transmitting and receiving information to and from the gas related digital twin 316 as well as a process recipe related digital twin 1013 and a temperature related digital twin 1017.

As illustrated in FIG. 11, the gas related digital twin 316 and the gas related digital twin 1016 may be connected via the transmission paths to an entire gas related digital twin 1102 that controls them.

The entire gas related digital twin 1102 controls the gas related digital twin included in each of the cyber spaces. To be more specific, the entire gas related digital twin 1102 transmits and receives information to and from the gas related digital twins 316 and 1016, and transmits various instructions to each gas related digital twin to optimize the target values of the entire Fab (i.e., the entire physical spaces).

The entire gas related digital twin 1102 may be included in one of the cyber spaces 310 and 1010, or may be included in a cyber space formed by other devices (for example, the server devices 110_1 to 110_3).

### SUMMARY

As is clear from the above description, in the cyber-physical system 1000, the management system that forms the cyber spaces and manages the substrate manufacturing processes of the physical spaces includes:
digital twins included in each of the cyber spaces, the digital twins respectively including agent units that monitor a state of a corresponding substrate processing device and detect that a predetermined event has occurred; and
a transmission path, connecting the digital twins included in different cyber spaces, through which, when the predetermined event is detected in an agent unit of a digital twin included in any one of the cyber spaces, information is transmitted to and received from an agent unit of a digital twin included in another cyber space, based on the detected event;
wherein the agent unit in which the predetermined event is detected derives an instruction to the substrate processing device based on the information transmitted and received via the transmission path so that an index value of the substrate manufacturing process is optimized, and
in this case, a digital twin that controls the digital twins included in each of the cyber spaces may be further provided to derive an instruction so that the entire physical spaces are optimized.

As described above, in addition to the configuration of the management system according to the first embodiment, the management system according to the second embodiment has a configuration in which digital twins included in different cyber spaces are cooperated. Thus, the management system according to the second embodiment can make each substrate processing device autonomous to optimize entire physical spaces.

### Third Embodiment

In the first and second embodiments, it has been described that a digital twin corresponding to each function of the substrate processing device is formed in the cyber space. In other words, the case where a digital twin is formed for each function in the cyber space has been described.

In the third embodiment, a digital twin is formed for each operation of hardware for realizing functions in the substrate processing device. Hereinafter, the third embodiment will be described focusing on differences from the first and second embodiments.

### <Functional Configuration of Cyber-Physical System>

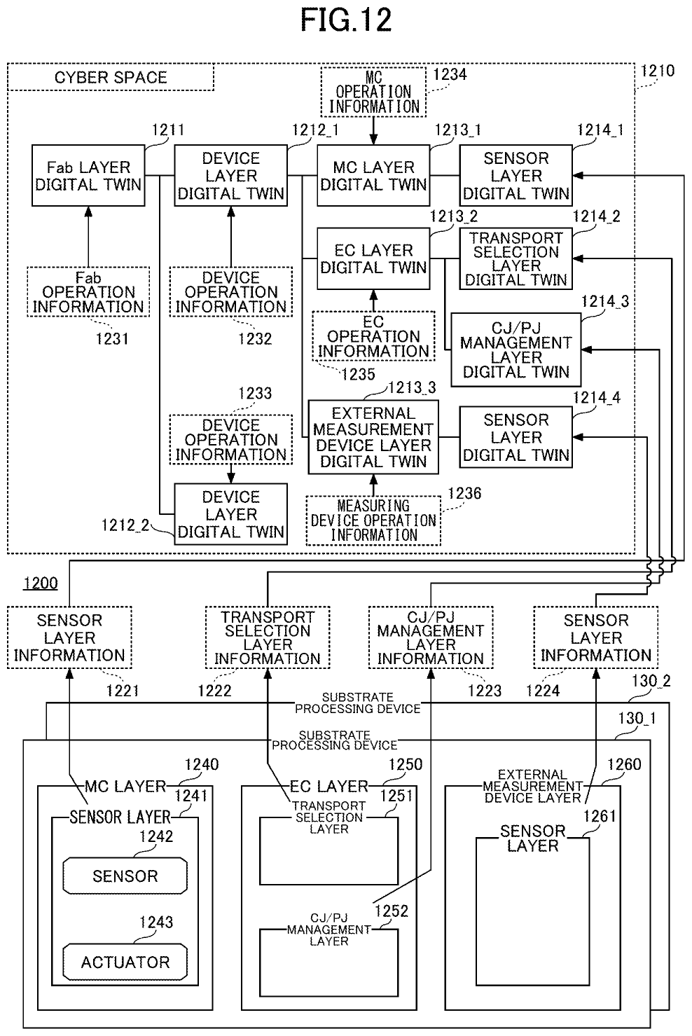

First, a functional configuration of a cyber-physical system according to the third embodiment will be described. FIG. 12 is a diagram illustrating a functional configuration example of the cyber-physical system according to the third embodiment.

As illustrated in FIG. 12, in a cyber-physical system 1200, a cyber space 1210 formed by the management devices 120_1 to 120_n includes digital twins formed corresponding to respective operations of the hardware for realizing the functions of the substrate processing device.

The example in FIG. 12 illustrates that a Fab layer digital twin 1211 formed for each Fab and device layer digital twins 1212_1 and 1212_2 formed respective devices of the substrate processing devices are included.

Further, the example in FIG. 12 illustrates that an MC layer digital twin 1213_1 formed for each MC, an EC layer digital twin 1213_2 formed for each EC, and an external measurement device layer digital twin 1213_3 formed for each external measurement device are included.

The example in FIG. 12 also illustrates that sensor layer digital twins 1214_1 and 1214_4 corresponding to respective sensors are included. Further, the example in FIG. 12 illustrates that a transport selection layer digital twin 1214_2 formed for each transport selection and a CJ/PJ management layer digital twin 1214_3 formed for each CJ/PJ management are included.

As illustrated in FIG. 12, the digital twins included in the cyber space 1210 have a hierarchical structure according to the hierarchical relationship of the respective operations. For example, in the case of FIG. 12, in the cyber space 1210, the Fab layer digital twin 1211 corresponding to the Fab is arranged in the highest level.

The following digital twins corresponding to the substrate processing devices 130_1 and 130_2 arranged in the Fab: the device layer digital twin 1212_1 and the device layer digital twin 1212_2 are arranged at the second level in the cyber space 1210.

The following digital twins corresponding to an MC layer 1240, an EC layer 1250, and an external measurement device layer 1260 arranged in the substrate processing device 130_1: the MC layer digital twin 1213_1, the EC layer digital twin 1213_2, and the external measurement device layer digital twin 1213_3 are arranged at the third level in the cyber space 1210.

Further, the sensor layer digital twin 1214_1 corresponding to a sensor layer 1241 arranged in the MC layer 1240 is arranged at the fourth level in the cyber space 1210. Furthermore, the transport selection layer digital twin 1214_2 and the CJ/PJ management layer digital twin 1214_3 corresponding to a transport selection layer 1251 and a CJ/PJ management layer 1252 arranged in the EC layer 1250 are arranged in the fourth level in the cyber space 1210. In addition, the sensor layer digital twin 1214_4 corresponding to a sensor layer 1261 arranged in the external measurement device layer 1260 is arranged in the fourth level in the cyber space 1210.

As illustrated in FIG. 12, information on each operation arranged in the lowest level in the physical space is input into the lowest level (the fourth level in the example in FIG. 12) in the cyber space 1210.

Specifically, as information on the sensor layer 1241 arranged in the MC layer 1240 of the substrate processing device 130_1, sensor layer information 1221 is input into the sensor layer digital twin 1214_1.

Further, as information on the transport selection layer 1251 arranged in the EC layer 1250 of the substrate processing device 130_1, transport selection layer information 1222 is input into the transport selection layer digital twin 1214_2. Also, as information on the CJ/PJ management layer 1252 arranged in the EC layer 1250 of the substrate processing device 130_1, CJ/PJ management layer information 1223 is input into the CJ/PJ management layer digital twin 1214_3.

Further, as information on the sensor layer 1261 arranged in the external measurement device layer 1260 of the substrate processing device 130_1, sensor layer information 1224 is input into the sensor layer digital twin 1214_4.

Further, as illustrated in FIG. 12, with respect to a digital twin in a level (the highest level, the second level, or the third level in the example in FIG. 12) other than the lowest level in the cyber space 1210, operation information on a corresponding operation is input.

For example, Fab operation information 1231 is input into the Fab layer digital twin 1211, device operation information 1232 is input into the device layer digital twin 1212_1, and device operation information 1233 is input into the device layer digital twin 1212_2. In addition, MC operation information 1234 is input into the MC layer digital twin 1213_1, EC operation information 1235 is input into the EC layer digital twin 1213_2, and measuring device operation information 1236 is input into the external measurement device layer digital twin 1213_3.

As illustrated in FIG. 12, in the cyber space 1210, the digital twins arranged in each level are connected to a digital twin arranged in one level higher and to a digital twin arranged in one level lower via the transmission paths.

For example, the device layer digital twin 1212_1 arranged in the second level is connected to the Fab layer digital twin 1211 that is the digital twin arranged in one level higher than the second level, via the transmission path. The device layer digital twin 1212_1 arranged in the second level is also connected to the MC layer digital twin 1213_1 to the external measurement device layer digital twin 1213_3 that are the digital twins arranged in one level lower than the second level via the transmission paths. Hereinafter, since the same connection applies to the other digital twins, the description thereof is omitted here.

### <Various Processes Performed in Cyber-Physical System>

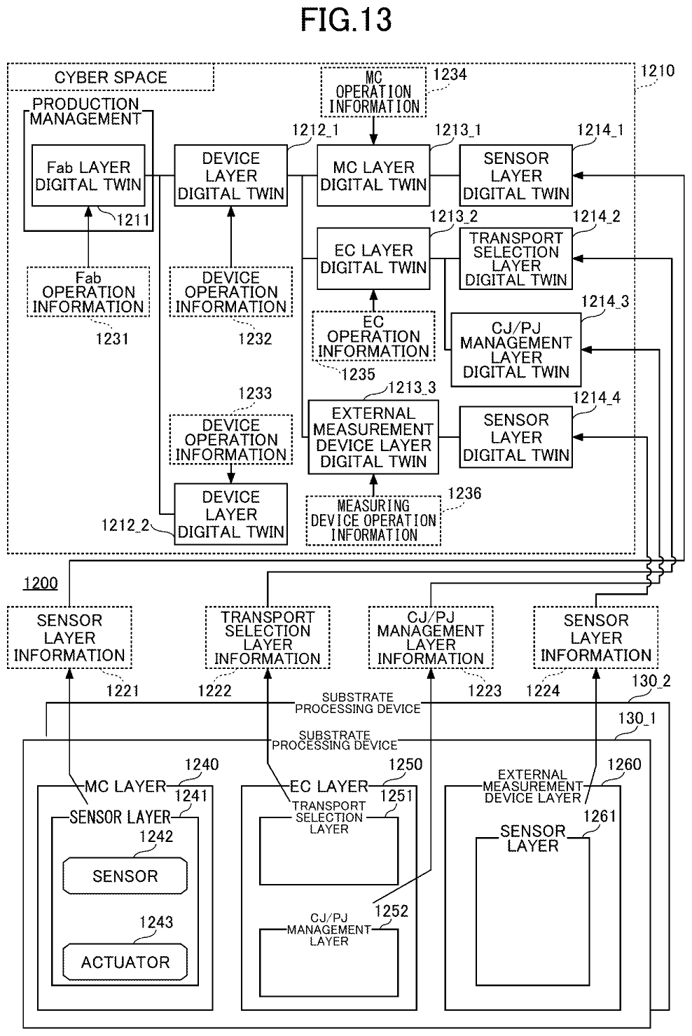

Next, various processes performed in the cyber-physical system 1200 will be described. FIG. 13 is a diagram illustrating an example of various processes performed in the cyber-physical system according to the third embodiment.

As in the above-described embodiments, in FIG. 13, a process indicated by a thick black frame represents an example of a process performed mainly by a corresponding digital twin. As illustrated in FIG. 13, for example, the Fab layer digital twin 1211 performs production management processing.

The production management processing is processing for managing a processing amount to be processed by the entire Fab and managing a processing amount assigned to each substrate processing device.

In the Fab layer digital twin 1211, for example, the processing amount to be processed next by the entire Fab is calculated based on the current operation information (the Fab operation information 1231) of the corresponding operation (the entire Fab), and the processing amount to be assigned to each of the substrate processing devices 130_1 and 130_2 is determined. Also, in the Fab layer digital twin 1211, the conversation contents including the determined processing amount are transmitted via the transmission paths to each of the device layer digital twins 1212_1 and 1212_2 arranged in one level lower than the level in which the Fab layer digital twin 1211 is arranged.

In response to the transmission of the conversation contents including the determined processing amount, there is a case where the conversation contents (response) indicating that the determined processing amount cannot be processed is transmitted from the device layer digital twin 1212_1 or 1212_2 arranged in the one level lower.

In this case, the Fab layer digital twin 1211 changes the processing amount assigned to each of the substrate processing devices 130_1 and 130_2. The Fab layer digital twin 1211 then transmits the conversation contents including the changed processing amount to each of the device layer digital twins 1212_1 and 1212_2 arranged in the one level lower.

As described above, the Fab layer digital twin 1211 calculates the processing amount to be processed next by the entire Fab based on the current operation information of the entire Fab, and determines the processing amount to be assigned to each substrate processing device. The Fab layer digital twin 1211 can also change the processing amount to be assigned by transmitting and receiving information to and from the device layer digital twins.

The production management processing illustrated in FIG. 13 is an example of a process performed in the cyber-physical system 1200, and the Fab layer digital twin 1211 may perform processing other than the production management processing. Further, the digital twin to mainly perform the production management processing is not limited to the Fab layer digital twin 1211, and any digital twin whose processing is not illustrated in FIG. 13 may mainly perform any processing as desired.

Here, the production management processing performed by the Fab layer digital twin 1211 will be described in detail below.

### <Outline of Functional Configuration of Fab Layer Digital Twin>

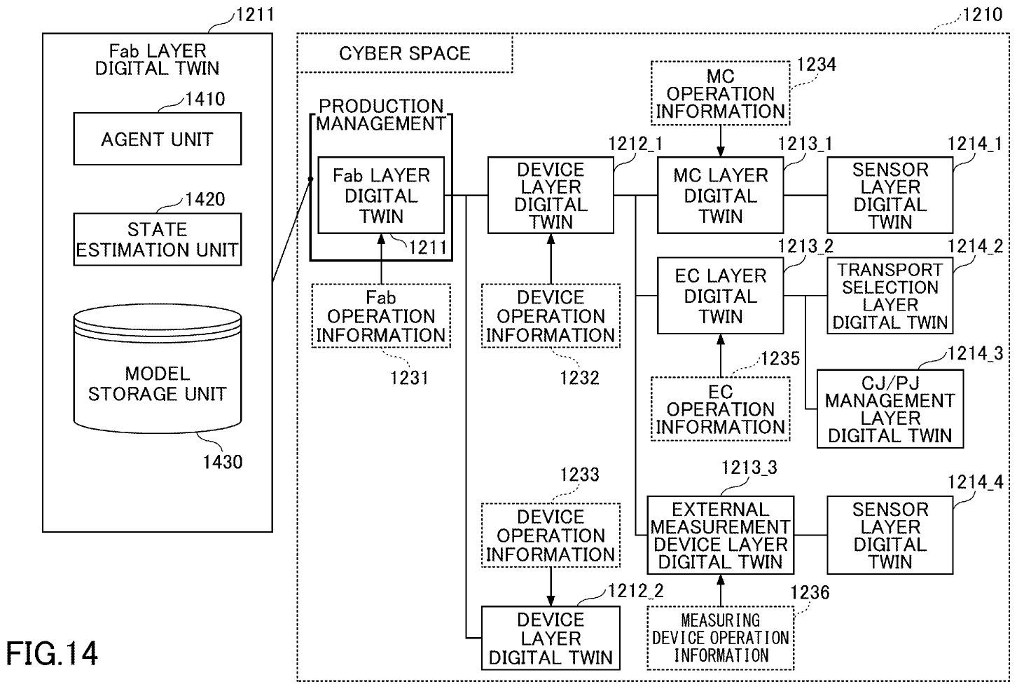

First, an outline of a functional configuration of the Fab layer digital twin that performs the production management processing will be described. FIG. 14 is a diagram illustrating the outline of the functional configuration of the Fab layer digital twin.

As illustrated in FIG. 14, the Fab layer digital twin 1211 includes an agent unit 1410 and a state estimation unit 1420, as functional blocks for performing the production management processing. A model included in each unit is stored in a model storage unit 1430, and is read out from the model storage unit 1430 when the production management processing is performed.

The agent unit 1410 manages the state estimation unit 1420. Specifically, the agent unit 1410 ascertains state information indicating the state of the corresponding operation (the entire Fab) estimated by the state estimation unit 1420 in real time, and calculates the processing amount to be processed next by the entire Fab. The agent unit 1410 also determines the processing amount to be assigned to each substrate processing device.

The agent unit 1410 also transmits the conversation contents including the determined processing amount to the device layer digital twins 1212_1 and 1212_2 arranged in one level lower. The agent unit 1410 also derives optimum processing amounts to be assigned, by repeating the transmission and reception of the conversation contents to and from the device layer digital twins 1212_1 and 1212_2 arranged in one level lower, and transmits the derived amounts to the device layer digital twins 1212_1 and 1212_2.

The state estimation unit 1420 obtains the current operation information (the Fab operation information 1231) of the corresponding operation (the entire Fab), and estimates the state information indicating the state of the corresponding operation (the entire Fab) using the obtained Fab operation information 1231 as input. Further, the state estimation unit 1420 transmits the estimated state information to the agent unit 1410.

Although the functional configuration of the Fab layer digital twin is illustrated in FIG. 14, when the production management processing is performed, substantially the same processing is performed in the other digital twins, under substantially the same functional configuration.

### <Details of Functional Configuration of Fab Layer Digital Twin 1211>

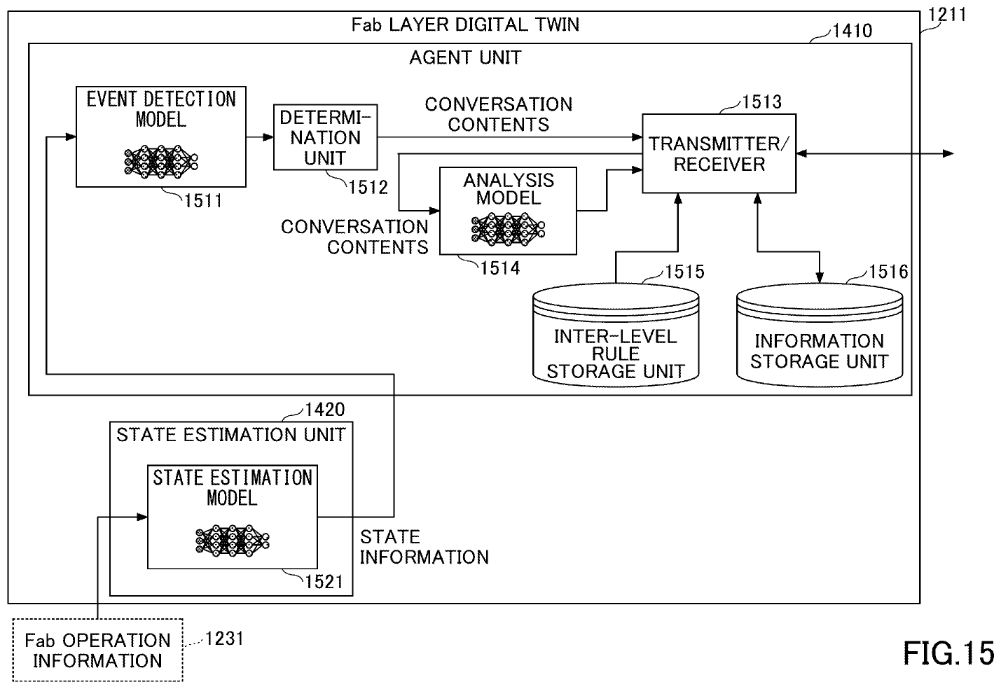

Next, the functional configuration of the Fab layer digital twin 1211 that performs the production management processing will be described in detail. FIG. 15 is a diagram illustrating details of the functional configuration of the Fab layer digital twin.

As illustrated in FIG. 15, the state estimation unit 1420 includes a state estimation model 1521. The state estimation model 1521 estimates the state information indicating the state of the entire Fab, using the Fab operation information 1231 as input. The state information estimated by the state estimation model 1521 includes any information as desired on the state of the entire Fab.

The agent unit 1410 includes an event detection model 1511, a determination unit 1512, a transmitter/receiver 1513, and an analysis model 1514.

The event detection model 1511 estimates whether an event requiring a change occurs and the type of the event with respect to the processing amount to be processed next by the entire Fab, using the state information estimated by the state estimation model 1521 as input.

When the event detection model 1511 estimates that no event has occurred, the determination unit 1512 calculates a processing amount to be processed next by the entire Fab based on the current operation information, and calculates a processing amount to be assigned to each substrate processing device. The determination unit 1512 also notifies the transmitter/receiver 1513 of the conversation contents including the processing amount assigned to each substrate processing device.

At this time, the determination unit 1512 calculates the processing amount to be processed next by the entire Fab and the processing amount to be assigned to each substrate processing device to optimize the index value of the entire substrate manufacturing process (here, the entire Fab). The index value referred to here is substantially the same as that in the first embodiment, and includes sub-index values such as a yield of the entire substrate manufacturing process, a processing amount per unit time of the entire substrate manufacturing process, and energy consumption of the entire substrate manufacturing process.

When the event detection model 1511 estimates that the event has occurred, the determination unit 1512 obtains the type of the event from the event detection model 1511. The determination unit 1512 also changes the processing amount to be processed next by the entire Fab based on the obtained type of event, and changes the processing amount to be assigned to each substrate processing device. In addition, the determination unit 1512 notifies the transmitter/receiver 1513 of the conversation contents including the processing amount assigned to each substrate processing device.

The transmitter/receiver 1513 transmits the conversation contents notified from the determination unit 1512 to the device layer digital twins arranged in one level lower than the determination unit. Further, the transmitter/receiver 1513 receives the conversation contents (response) transmitted from the device layer digital twins arranged in one level lower, and inputs the conversation contents into the analysis model 1514. Furthermore, the transmitter/receiver 1513 transmits the conversation contents output from the analysis model 1514 to the device layer digital twins arranged in one level lower.

When the transmitter/receiver 1513 transmits and receives the conversation contents to and from the device layer digital twins arranged in one level lower, the transmission and reception are performed in accordance with inter-level rules stored in an inter-level rule storage unit 1515.

In addition, the conversation contents transmitted and received between the transmitter/receiver 1513 and the device layer digital twins arranged in one level lower are stored in an information storage unit 1516.

The analysis model 1514 outputs the conversation contents to be transmitted to the device layer digital twins arranged in one level lower, using the conversation contents (response) notified from the transmitter/receiver 1513 as input. In the case of the production management processing, information on the executability with respect to the assigned processing amounts transmitted to the device layer digital twins arranged in one level lower is transmitted from one of the device layer digital twins arranged in one level lower. The analysis model 1514 then calculates new processing amounts to be assigned by using the information on the executability transmitted from the device layer digital twin arranged in one level lower as input.

The analysis model 1514, by repeating the transmission and reception of the conversation contents with the device layer digital twins arranged in one level lower, derives optimum processing amounts to be assigned, and transmits the derived amounts to the device layer digital twins arranged in one level lower.

Since the example in FIG. 15 is the description of the functional configuration of the Fab layer digital twin 1211 arranged in the highest level, the transmitter/receiver 1513 transmits the conversation contents only to the digital twin arranged in one level lower. However, in the case of a digital twin arranged in the non-highest level, the conversation contents are transmitted to both a digital twin arranged in a level lower by one level and a digital twin arranged in a level higher by one level. Here, which conversation contents are transmitted to which digital twins arranged in which level is determined in accordance with the inter-level rules stored in the inter-level rule storage unit 1515.

### Specific Example of Conversation Contents Transmitted and Received Between Levels in Production Management Processing

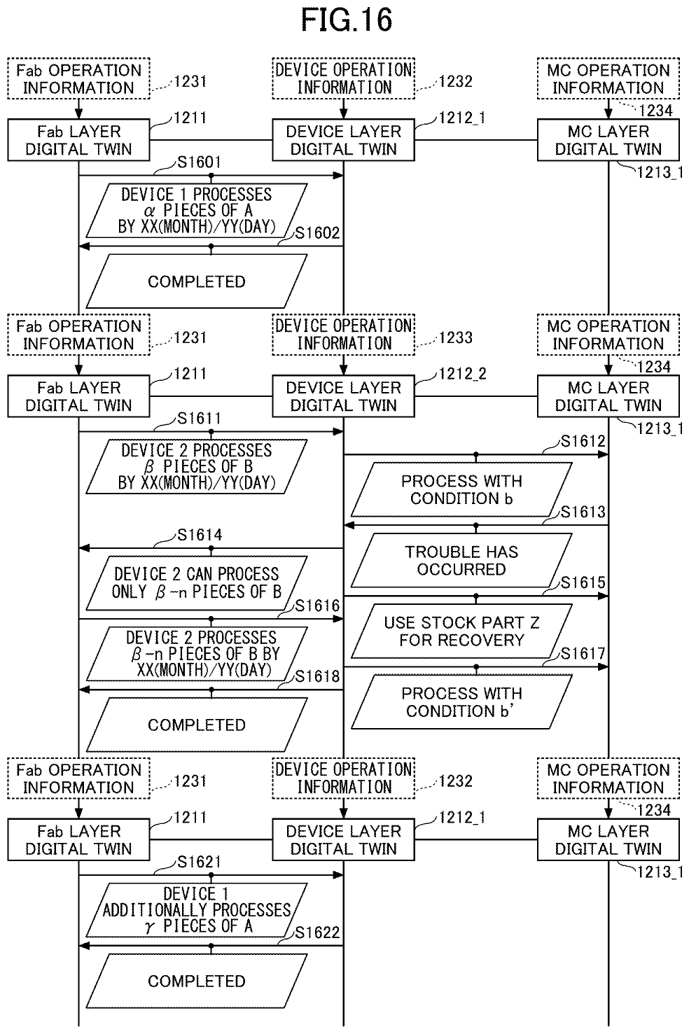

Next, a specific example of the conversation contents transmitted and received between levels in the production management processing by the Fab layer digital twin 1211 will be described. FIG. 16 is a diagram illustrating an example of the conversation contents transmitted and received between the levels during the production management processing.

In step S1601, the Fab layer digital twin 1211 determines the occurrence of the event from the state information estimated based on the Fab operation information 1231, and then calculates a processing amount to be processed next by the entire Fab. The Fab layer digital twin 1211 also calculates the processing amounts to be assigned to the substrate processing devices 130_1 and 130_2. Among the processing amounts, the Fab layer digital twin 1211 transmits, to the device layer digital twin 1212_1, “Device 1 processes α pieces of A by XX(month)/YY(day)” as conversation contents including the processing amount assigned to the substrate processing device 130_1.

In step S1602, in response to the transmission of the conversation contents, the Fab layer digital twin 1211 receives “completed” as the conversation contents (response) from the device layer digital twin 1212_1.

Subsequently, in step S1611, the Fab layer digital twin 1211 transmits, to the device layer digital twin 1212_2, “Device 2 processes R pieces of B by XX(month)/YY(day)” as conversation contents including the processing amount assigned to the substrate processing device 130_2.

In step S1612, the device layer digital twin 1212_2 outputs conversation contents to be transmitted to the MC layer digital twin 1213_1 based on the conversation contents transmitted from the Fab layer digital twin 1211. Specifically, “Process with condition b” is output as the conversation contents and transmitted to the MC layer digital twin 1213_1. It is assumed that a trouble (an event requiring a change in the processing amount to be processed next by the substrate processing device 130_2) occurs in the MC layer 1240 at this timing.

In step S1613, the MC layer digital twin 1213_1 detects that an event requiring a change in the processing amount to be processed next has occurred, and transmits “Trouble has occurred” as the conversation contents to the device layer digital twin 1212_2.

In step S1614, the device layer digital twin 1212_2 derives the amount of the processing that can be performed by the substrate processing device 130_2 based on the conversation contents (response) transmitted from the MC layer digital twin 1213_1. The device layer digital twin 1212_2 then transmits “Device 2 can process only (β-n) pieces of B” as the conversation contents including the derived processing amount to the Fab layer digital twin 1211.

In step S1615, the device layer digital twin 1212_2 derives an optimum solution for the trouble based on the conversation contents (response) transmitted from the MC layer digital twin 1213_1. Further, the device layer digital twin 1212_2 transmits “Use stock part Z for recovery” as the conversation contents including the derived solution to the MC layer digital twin 1213_1.

In step S1616, the Fab layer digital twin 1211 changes the processing amounts assigned to the substrate processing devices 130_1 and 130_2 based on the conversation contents (response) transmitted from the device layer digital twin 1212_2. Among the processing amounts, the Fab layer digital twin 1211 transmits to the device layer digital twin 1212_2 “Device 2 processes (β-n) pieces of B by XX(month)/YY(day)” as the conversation contents including the processing amount assigned to the substrate processing device 130_2 after the amount to be assigned is changed.

In step S1617, the device layer digital twin 1212_2 outputs the conversation contents to be transmitted to the MC layer digital twin 1213_1 based on the conversation contents transmitted from the Fab layer digital twin 1211. Specifically, “Process with condition b′” is output as the conversation contents and transmitted to the MC layer digital twin 1213_1.

In step S1618, in response to the transmission of the conversation contents including the processing amount after the amount to be assigned is changed, the Fab layer digital twin 1211 receives “Completed” as the conversation contents (response) from the device layer digital twin 1212_2.

In step S1621, the Fab layer digital twin 1211 transmits “Device 1 additionally processes γ pieces of A” to the device layer digital twin 1212_1 as the conversation contents including the processing amount after the amount to be assigned is changed.

In step S1622, in response to the transmission of the conversation contents including the processing amount after the amount to be assigned is changed, the Fab layer digital twin 1211 receives “Completed” as the conversation contents (response) from the device layer digital twin 1212_1.

### <Production Management Processing Flow>

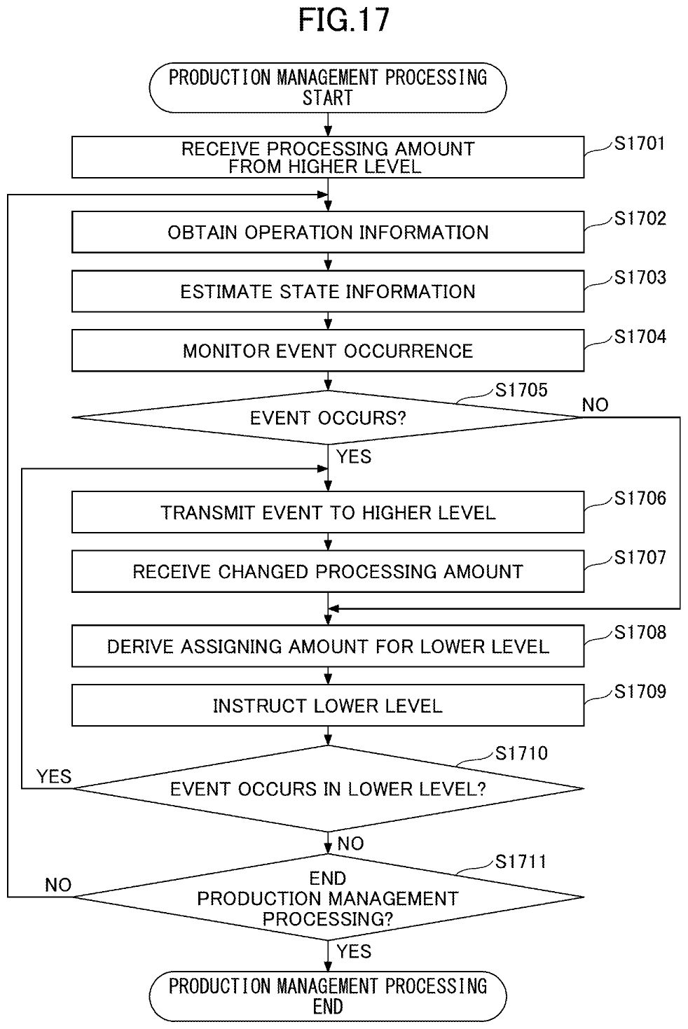

Next, a production management processing flow will be described. FIG. 17 is a flowchart illustrating the production management processing flow. In FIG. 17, an operation of a digital twin arranged in a predetermined level other than the highest level at the time of the production management processing will be described.

In step S1701, the digital twin arranged in the predetermined level receives the conversation contents including the assigned processing amount from the digital twin arranged in a level higher by one level.

In step S1702, the digital twin arranged in the predetermined level obtains the current operation information of the corresponding operation.

In step S1703, the digital twin arranged in the predetermined level estimates the state information indicating the state of the corresponding operation based on the obtained operation information.

In step S1704, based on the estimated state information, the digital twin arranged in the predetermined level monitors whether an event, requiring a change in the processing amount to be processed next by the corresponding operation, occurs.

In step S1705, the digital twin arranged in the predetermined level determines whether the event requiring a change in the processing amount has occurred and the type of the event. When it is determined in step S1705 that the event has not occurred (NO in step S1705), the process proceeds to step S1708.

When it is determined in step S1705 that the event has occurred (YES in step S1705), the process proceeds to step S1706.

In step S1706, the digital twin arranged in the predetermined level transmits, to the digital twin arranged in the level higher by one level, the conversation contents including the occurred event and the amount of the processing that can be performed.

In step S1707, the digital twin arranged in the predetermined level receives the processing amount after the amount to be assigned is changed from the digital twin arranged in the level higher by one level.

In step S1708, the digital twin arranged in the predetermined level derives the processing amount to be assigned to the digital twin arranged in the level lower by one level based on the received processing amount.

In step S1709, the digital twin arranged in the predetermined level transmits the conversation contents including the assigned processing amount to the digital twin arranged in the level lower by one level.

In step S1710, the digital twin arranged in the predetermined level determines whether the conversation contents (response) including the event are received from the digital twin arranged in the level lower by one level. When it is determined in step S1710 that the conversation contents (response) including the event is received (YES in step S1710), the process returns to step S1706.

In step S1710, when it is determined that the conversation contents (response) including the event are not received (NO in step S1710), the process proceeds to step S1711.

In step S1711, the digital twin arranged in the predetermined level determines whether to end the production management processing. When it is determined in step S1711 that the production management processing is not to be ended (NO in step S1711), the process returns to step S1702.

When it is determined in step S1711 that the production management processing is to be ended (YES in step S1711), the production management processing is ended.

### SUMMARY

As is clear from the above description, in the cyber-physical system 1200, the management system that forms the cyber space and manages the substrate manufacturing process in the physical space includes:
digital twins that are formed corresponding to respective operations of the hardware for realizing the function of each substrate processing device and have the hierarchical structure according to the hierarchical relationship of respective operations; and
a transmission path that connects the digital twins so that information based on an event detected in any one of the digital twins (for example, the changed processing amount to be assigned) is transmitted and received between the digital twins arranged in different levels.

As described above, by forming the digital twins corresponding to respective operations and transmitting and receiving the information via the transmission paths according to the hierarchical structure, the management system according to the third embodiment can receive substantially the same effects as those of the first and second embodiments. In addition, in the management system according to the third embodiment, it is possible to efficiently perform specific processes such as the production management processing.

### OTHER EMBODIMENTS

In the first to third embodiments, the management devices 120_1 to 120_n are configured as separate management devices, however, the management devices 120_1 to 120_n may be configured as an integrated device. In this case, n management devices may be configured to operate virtually (that is, as virtual machines) on a single device.

In the first to third embodiments, each of the management devices 120_1 to 120_n corresponding to the substrate processing devices 130_1 to 130_n has been described as a device executing the management program, alone. However, one management device (for example, the management device 120_1) corresponding to one substrate processing device (for example, the substrate processing device 130_1) may be configured by, for example, multiple computers. Also, by installing the management program in each of the computers, the management program may be executed in a form of distributed computing.

In addition, in the first to third embodiments, as an example of a method of installing a management program in the auxiliary storage devices 203 of the management devices 120_1 to 120_n, a method of downloading and installing the management program via a network has been described. At this time, although the download source is not particularly mentioned, when the management program is installed by such a method, the download source may be, for example, a server device in which the management program is accessibly stored. In addition, the server device may be a device on the Cloud that receives access from each of the management devices 120_1 to 120_n via the network and downloads the management program on condition of charging. That is, the server device may be a device on the Cloud that provides management program provisioning services.

In the first to third embodiments, it is described that the cyber space is formed in the management system including the management devices 120_1 to 120_n. However, the cyber space may be formed in a system other than the management system. For example, a cyber space may be formed in the server devices 110_1 to 110_3.

Although the details of the model are not mentioned in the first to third embodiments, the model used in the first to third embodiments may be, for example, a machine learning model including deep learning. For example, the model may be any of the following:
RNN (Recurrent Neural Network);
LSTM (Long Short-Term Memory);
CNN (Convolutional Neural Network);
R-CNN (Region based Convolutional Neural Network);
YOLO (You only look once);
SSD (Single Shot MultiBox Detector);
GAN (Generative Adversarial Network);
SVM (Support Vector Machine);
a decision tree; and
Random Forest.

Alternatively, a model using a genetic algorithm such as GA (Genetic Algorism) or GP (Genetic Programming) or a model trained by reinforcement learning may be used.

Alternatively, the model used in the first to third embodiments may be a model obtained by general statistical analysis other than deep learning, such as PCR (Principal Component Regression), PLS (Partial Least Square), LASSO, ridge regression, linear polynomial, autoregressive model, moving average model, autoregressive moving average model, and ARX model. A combination of the above models may also be used.

When the machine learning model is trained, for example, data used as “input” and data to be “estimated” in the description of FIG. 8 may be obtained in advance, and training data in which the respective pieces of data are set as “input data” and “correct data” may be used.

Although the three connection modes are described in the first embodiment, the digital twin connection mode is not limited thereto. Further, the connection mode may be changed according to the process that each digital twin performs mainly.

Note that the present disclosure is not limited to the configurations or combinations with other elements described above. These can be modified to the extent that it does not depart from the intent of the present disclosure, and can be appropriately defined according to the form of its application.

This application is based upon and claims the benefit of priority from Japanese Patent Application No. 2020-217779 filed on Dec. 25, 2020, the entire content of which is incorporated herein by reference.

### LIST OF REFERENCE NUMERALS

100 Cyber-physical system
120_1 to 120_n Management device
130_1 to 130_n Substrate processing device
310 Cyber space
330 Physical space
710 Agent unit
720 State estimation unit
730 Model prediction controller
811 Event detection model
812 Determination unit
813 Transmitter/receiver
814 Analysis model
821 State estimation model
831 Prediction model
832 Objective function unit
833 Optimization unit
834 Verification unit
1000 Cyber-physical system
1010 Cyber space
1200 Cyber-physical system
1210 Cyber space
1410 Agent unit
1420 State estimation unit
1511 Event detection model
1512 Determination unit
1513 Transmitter/receiver
1514 Analysis model
1521 State estimation model

1. A management system for managing a substrate manufacturing process, comprising:
a substrate processing device that performs the substrate manufacturing process; and
a management device including a processor and a memory,
wherein the processor causes each of agent units in the management device to monitor a state of the substrate processing device and detect a predetermined event; and
wherein, in response to a first agent unit among the agent units detecting a predetermined event, information is transmitted and received between the agent units based on the detected event,
wherein the first agent unit derives an instruction to the substrate processing device based on the information transmitted and received between the agent units so that an index value of the substrate manufacturing process is optimized.

2. The management system according to claim 1, comprising:
a model storage unit configured to store a state estimation model for estimating the state of the substrate processing device based on information obtained from the substrate manufacturing process;
wherein the processor is further configured to acquire the state of the substrate processing device that is estimated by inputting the information obtained from the substrate manufacturing process into the state estimation model; and
detect the predetermined event in the substrate processing device from the acquired state of the substrate processing device.

3. The management system according to claim 2, wherein the model storage unit further stores a prediction model for reproducing a control system of the substrate processing device,
wherein the processor is further configured to determine whether it is necessary to transmit and receive information to and from another agent unit based on a type of the detected event;
transmit information based on the detected event to another agent unit in a case where it is determined that it is necessary to transmit and receive the information to and from the another agent unit;
receive a response from the another agent unit in response to the transmission of the information based on the detected event;
store the information transmitted to and received from the another agent unit;
optimize a control value so that the prediction model outputs a target value calculated based on the response from the another agent unit; and
control the control system using the optimized control value.

4. The management system according to claim 3, wherein the processor determines whether it is necessary to transmit and receive the information to and from the another agent unit by determining control availability based on an error between the output of the prediction model when the processor optimizes the control value so that the prediction model outputs the target value according to the type of the detected event and the target value according to the type of the detected event.

5. The management system according to claim 3, wherein the processor newly acquires the state of the substrate processing device by inputting information newly obtained from the substrate manufacturing process into the state estimation model in response to the control using the optimized control value.

6. The management system according to claim 5,
wherein the processor is further configured to verify prediction accuracy of the prediction model based on the newly obtained information, and
adjust a model parameter of the prediction model based on the prediction accuracy.

7. The management system according to claim 1, wherein each of the agent units is connected to all other agent units or some other agent units.

8. The management system according to claim 1, wherein a transmission/reception direction is defined in advance for each connection destination when each of the agent units transmits and receives information to and from another agent unit.

9. The management system according to claim 3, wherein the agent units are arranged in association with levels in a hierarchical structure based on each operation of the substrate manufacturing process, and
wherein the agent units are connected so that the information based on the detected event is transmitted and received between the agent units associated with different levels.

10. The management system according to claim 9, wherein the agent units further include a rule storage unit configured to store a rule between levels for transmitting and receiving information based on the detected event between the agent units associated with the different levels.

11. The management system according to claim 10, wherein the processor transmits information calculated based on information received from an agent unit associated with another level to an agent unit associated with another level in accordance with the rule between the levels.

12. The management system according to claim 3, wherein agent units are connected included in different cyber spaces so that information is transmitted and received between corresponding agent units among the agent units included in the different cyber spaces.

13. A management method of managing a substrate manufacturing process, comprising:
detecting, by agent units, a predetermined event by monitoring a state of a substrate processing device that performs the substrate manufacturing process; and
in response to a first agent unit among the agent units detecting a predetermined event, transmitting and receiving information between the agent units based on the detected event,
wherein the first agent unit derives an instruction to the substrate processing device based on the information transmitted and received so that an index value of the substrate manufacturing process is optimized.

14. A non-transitory computer-readable recording medium having stored therein a management program for causing a computer of a management system for managing a substrate manufacturing process to perform a process comprising:
detecting, by agent units, a predetermined event by monitoring a state of a substrate processing device that performs the substrate manufacturing process; and
in response to a first agent unit among the agent units detecting a predetermined event, transmitting and receiving information between the agent units based on the detected event,
wherein the first agent unit derives an instruction to the substrate processing device based on information transmitted and received so that an index value of the substrate manufacturing process is optimized.

15. The management system according to claim 1, wherein each of the agent units includes an analysis model configured to output a target value based on the information transmitted and received between the agent units, the information including an allowable target value or a constraint condition.
